(19) United States
(12) Patent Application Publication
(10) Pub. No.: US 2024/0006445 A1
(43) Pub. Date: Jan. 4, 2024

(54) LIGHT RECEIVING ELEMENT, PHOTODETECTOR, AND DISTANCE MEASUREMENT SYSTEM

(71) Applicant: SONY SEMICONDUCTOR SOLUTIONS CORPORATION, Kanagawa (JP)

(72) Inventors: Junki SUZUKI, Kanagawa (JP); Yusuke OTAKE, Kanagawa (JP)

(73) Assignee: SONY SEMICONDUCTOR SOLUTIONS CORPORATION, Kanagawa (JP)

(21) Appl. No.: 18/253,880

(22) PCT Filed: Nov. 5, 2021
(86) PCT No.: PCT/JP2021/040769

§ 371 Date: May 22, 2023

(30) Foreign Application Priority Data
Dec. 2, 2020 (JP) 2020-200016

(51) Int. Cl. H01L 27/146; H01L 31/107; G01S 7/4863; G01S 17/894

(52) U.S. Cl. CPC H01L 27/1463; H01L 31/107; H01L 27/14607; G01S 7/4863; G01S 17/894

(57) ABSTRACT

Provided is a light receiving element in a semiconductor substrate and surrounded by a pixel isolation wall, the light receiving element including a multiplication region that amplifies a charge, a cathode unit on a surface of the multiplication region on an opposite side from a light receiving surface, a hole accumulation region covering the light receiving surface and an inner side surface of the pixel isolation wall, and an anode unit on a part of a surface of the hole accumulation region covering the inner side surface of the pixel isolation wall that is on the opposite side from the light receiving surface, wherein when the semiconductor substrate is viewed from above a surface on the opposite side from the light receiving surface, a center point of the multiplication region is farther from the anode unit than a center point of the light receiving element.

### FIELD

The present disclosure relates to a light receiving element, a photodetector, and a distance measurement system.

### BACKGROUND

In recent years, distance measurement systems that measure distances through a time of flight (ToF) method have attracted attention. As a light receiving element included in a distance measurement system, there is a light receiving element using a single photon avalanche diode (SPAD). The SPAD, in which single particles of light (photons) enter, and electrons (charges) generated by photoelectric conversion are multiplied in a PN junction region (avalanche amplification), can detect light with high accuracy. In the distance measurement system, distances can be measured with high accuracy by detecting the timing at which a current of the multiplied electrons flows.

### CITATION LIST

### Patent Literature

Patent Literature 1: WO 2018/074530 A

### SUMMARY

### Technical Problem

However, in the conventional distance measurement system using the SPAD, in which the withstand voltage decreases as the size of pixels (light receiving elements) is miniaturized, there is a limit to further miniaturizing pixels while securing a desired withstand voltage.

The present disclosure proposes a light receiving element, a photodetector, and a distance measurement system with which pixels can be further miniaturized while a desired withstand voltage is secured.

### Solution to Problem

According to the present disclosure, there is provided a light receiving element provided in a semiconductor substrate and surrounded by a pixel isolation wall. The light receiving element including: a photoelectric conversion unit that is provided in the semiconductor substrate and generates a charge with light incident from a light receiving surface of the semiconductor substrate; a multiplication region that is provided on an opposite side of the photoelectric conversion unit from the light receiving surface and amplifies a charge from the photoelectric conversion unit; a cathode unit provided on a surface of the multiplication region, the surface being on the opposite side from the light receiving surface; a hole accumulation region provided to cover the light receiving surface and an inner side surface of the pixel isolation wall; and an anode unit provided on a part of a surface of the hole accumulation region covering the inner side surface of the pixel isolation wall, the part of the surface being on the opposite side from the light receiving surface. In the light receiving element, when the semiconductor substrate is viewed from above a surface on the opposite side from the light receiving surface, the multiplication region is provided such that a center point of the multiplication region is farther from the anode unit than a center point of the light receiving element.

Furthermore, according to the present disclosure, there is provided a photodetector including: a pixel group including a plurality of pixels arranged in a matrix in a semiconductor substrate; and a pixel isolation wall surrounding each of the pixels and isolating the pixels from each other. In the photodetector, each of the pixels includes: a photoelectric conversion unit that is provided in the semiconductor substrate and generates a charge with light incident from a light receiving surface of the semiconductor substrate; a multiplication region that is provided on an opposite side of the photoelectric conversion unit from the light receiving surface and amplifies a charge from the photoelectric conversion unit; a cathode unit provided on a surface of the multiplication region, the surface being on the opposite side from the light receiving surface; a hole accumulation region provided to cover the light receiving surface and an inner side surface of the pixel isolation wall; and an anode unit provided on a part of a surface of the hole accumulation region covering the inner side surface of the pixel isolation wall surrounding the pixel group, the part of the surface being on the opposite side from the light receiving surface. In the photodetector, when the semiconductor substrate is viewed from above a surface on the opposite side from the light receiving surface, in at least one of the plurality of pixels included in the pixel group, the multiplication region is provided such that a center point of the multiplication region is closer to a center point of the pixel group than a center point of a corresponding pixel in the at least one of the plurality of pixels.

Furthermore, according to the present disclosure, there is provided a distance measurement system including: an illumination device that emits irradiation light; and a photodetector that receives reflected light obtained by reflecting the irradiation light on a subject. In the distance measurement system, the photodetector includes: a pixel group including a plurality of pixels arranged in a matrix in a semiconductor substrate; and a pixel isolation wall surrounding each of the pixels and isolating the pixels from each other. In the photodetector, each of the pixels includes: a photoelectric conversion unit that is provided in the semiconductor substrate and generates a charge with light incident from a light receiving surface of the semiconductor substrate; a multiplication region that is provided on an opposite side of the photoelectric conversion unit from the light receiving surface and amplifies a charge from the photoelectric conversion unit; a cathode unit provided on a surface of the multiplication region, the surface being on the opposite side from the light receiving surface; a hole accumulation region provided to cover the light receiving surface and an inner side surface of the pixel isolation wall; and an anode unit provided on a part of a surface of the hole accumulation region covering the inner side surface of the pixel isolation wall surrounding the pixel group, the part of the surface being on the opposite side from the light receiving surface. In the photodetector, when the semiconductor substrate is viewed from above a surface on the opposite side from the light receiving surface, in at least one of the plurality of pixels included in the pixel group, the multiplication region is provided such that a center point of the multiplication region is closer to a center point of the pixel group than a center point of a corresponding pixel in the at least one of the plurality of pixels.

### BRIEF DESCRIPTION OF DRAWINGS

FIG. 1 is an explanatory diagram for explaining an example of a circuit configuration of a pixel 10.

FIG. 2 is a graph illustrating a change in a cathode voltage VS of a photodiode 20 and a detection signal PFₒᵤₜ according to incidence of light.

FIG. 3 is a block diagram illustrating a configuration example of a photodetector 501.

FIG. 4 is a block diagram illustrating a configuration example of a distance measurement system 611 incorporating the photodetector 501.

FIG. 5 is a schematic sectional view illustrating an example of a detailed configuration of the pixel 10 according to Comparative Example.

FIG. 6 is a schematic plan view illustrating the example of a detailed configuration of the pixel 10 according to Comparative Example.

FIG. 7 is a schematic sectional view illustrating an example of a detailed configuration of the pixel 10 according to a first embodiment of the present disclosure.

FIG. 8 is a schematic plan view illustrating an example of a detailed configuration of the pixel 10 according to the first embodiment of the present disclosure.

FIG. 9 is a schematic plan view illustrating an example of a detailed configuration of the pixel 10 according to a modification of the first embodiment of the present disclosure.

FIG. 10 is a schematic plan view illustrating an example of a detailed configuration of the pixel 10 according to a second embodiment of the present disclosure.

FIG. 11 is a schematic plan view illustrating an example of a detailed configuration of the pixel 10 according to a modification of the second embodiment of the present disclosure.

FIG. 12 is a schematic sectional view illustrating an example of a detailed configuration of the pixel 10 according to a third embodiment of the present disclosure.

FIG. 13 is a schematic plan view illustrating an example of a detailed configuration of the pixel 10 according to the third embodiment of the present disclosure.

FIG. 14 is a schematic sectional view illustrating an example of a detailed configuration of the pixel 10 according to a fourth embodiment of the present disclosure.

FIG. 15 is a schematic plan view illustrating the example of a detailed configuration of the pixel 10 according to the fourth embodiment of the present disclosure.

FIG. 16 is a schematic plan view illustrating an example of a detailed configuration of the pixel 10 according to Modification 1 of the fourth embodiment of the present disclosure.

FIG. 17 is a schematic plan view illustrating an example of a detailed configuration of the pixel 10 according to Modification 2 of the fourth embodiment of the present disclosure.

FIG. 18 is a schematic sectional view illustrating an example of a detailed configuration of the pixel 10 according to a fifth embodiment of the present disclosure.

FIG. 19 is a schematic plan view illustrating the example of a detailed configuration of the pixel 10 according to the fifth embodiment of the present disclosure.

FIG. 20 is a schematic sectional view illustrating an example of a detailed configuration of the pixel 10 according to a sixth embodiment of the present disclosure.

FIG. 21 is a schematic sectional view illustrating an example of a detailed configuration of the pixel 10 according to a modification of the sixth embodiment of the present disclosure.

FIG. 22 is a schematic sectional view illustrating an example of a detailed configuration of the pixel 10 according to a seventh embodiment of the present disclosure.

FIG. 23 is a schematic plan view illustrating the example of a detailed configuration of the pixel 10 according to the seventh embodiment of the present disclosure.

FIG. 24 is a schematic plan view illustrating an example of a detailed configuration of the pixel 10 according to a modification of the seventh embodiment of the present disclosure.

FIG. 25 is a schematic plan view illustrating an example of a detailed configuration of the pixel 10 according to an eighth embodiment of the present disclosure.

FIG. 26 is a schematic plan view illustrating an example of a detailed configuration of the pixel 10 according to a modification of the eighth embodiment of the present disclosure.

FIG. 27 is a schematic sectional view illustrating an example of a detailed configuration of the pixel 10 according to a ninth embodiment of the present disclosure.

FIG. 28 is a schematic plan view illustrating the example of a detailed configuration of the pixel 10 according to the ninth embodiment of the present disclosure.

FIG. 29 is a schematic plan view illustrating an example of a detailed configuration of the pixel 10 according to Modification 1 of the ninth embodiment of the present disclosure.

FIG. 30 is a schematic plan view illustrating an example of a detailed configuration of the pixel 10 according to Modification 2 of the ninth embodiment of the present disclosure.

FIG. 31 is a schematic plan view illustrating an example of a detailed configuration of the pixel 10 according to Modification 3 of the ninth embodiment of the present disclosure.

FIG. 32 is a schematic sectional view illustrating an example of a detailed configuration of the pixel 10 according to a tenth embodiment of the present disclosure.

FIG. 33 is a schematic plan view illustrating an example of the detailed configuration of the pixel 10 according to the tenth embodiment of the present disclosure.

FIG. 34 is a schematic plan view illustrating an example of a detailed configuration of the pixel 10 according to a modification of the tenth embodiment of the present disclosure.

FIG. 35A is a schematic diagram (part 1) for explaining a method for producing the pixel 10 according to an eleventh embodiment of the present disclosure.

FIG. 35B is a schematic diagram (part 2) for explaining the method for producing the pixel 10 according to the eleventh embodiment of the present disclosure.

FIG. 35C is a schematic diagram (part 3) for explaining the method for producing the pixel 10 according to the eleventh embodiment of the present disclosure.

FIG. 35D is a schematic diagram (part 4) for explaining the method for producing the pixel 10 according to the eleventh embodiment of the present disclosure.

FIG. 35E is a schematic diagram (part 5) for explaining the method for producing the pixel 10 according to the eleventh embodiment of the present disclosure.

FIG. 35F is a schematic diagram (part 6) for explaining the method for producing the pixel 10 according to the eleventh embodiment of the present disclosure.

FIG. 36A is a schematic diagram (part 1) for explaining a method for producing the pixel 10 according to a modification of the eleventh embodiment of the present disclosure.

FIG. 36B is a schematic diagram (part 2) for explaining the method for producing the pixel 10 according to the modification of the eleventh embodiment of the present disclosure.

FIG. 36C is a schematic diagram (part 3) for explaining the method for producing the pixel 10 according to the modification of the eleventh embodiment of the present disclosure.

FIG. 37 is a block diagram illustrating a configuration example of a smartphone 900 as an electronic device to which a distance measurement system 611 according to an embodiment of the present disclosure is applied.

### DESCRIPTION OF EMBODIMENTS

Hereinafter, embodiments of the present disclosure will be described in detail with reference to the drawings. In each of the following embodiments, the same portions are denoted by the same reference signs, and repetitive description are omitted.

The drawings referred to in the following description are drawings for describing the embodiments of the present disclosure and promoting understanding thereof, and shapes, dimensions, ratios, and the like illustrated in the drawings may be different from actual ones for the sake of clarity. The photodetector illustrated in the drawings, components included in the photodetector, and the like may be appropriately modified in design in consideration of the following description and known technologies. In the following description, the vertical direction of a stacked structure of the photodetector corresponds to a relative direction in a case where the photodetector is disposed such that light incident on the photodetector is directed from bottom to top unless otherwise specified.

The description of specific shapes in the following description does not mean only geometrically defined shapes. In detail, the description of specific shapes in the following description include a case where there is an allowable difference (error/distortion) in pixels, the photodetector, their production methods, and their use/operation, and a shape similar to the shapes. For example, in the following description, the expression “substantially rectangular shape” is not limited to a quadrangle, and includes a shape similar to a quadrangle with any of the four corners being chamfered.

In the following description of circuits (electrical connections), unless otherwise specified, “electrically connected” means that a plurality of elements are connected to conduct electricity (signals). In addition, “electrically connected” in the following description includes not only a case of directly and electrically connecting a plurality of elements but also a case of indirectly and electrically connecting a plurality of elements via other elements.

In the present specification, the term “gate” refers to a gate electrode of a field effect transistor. The term “drain” refers to a drain region of a field effect transistor, and the term “source” refers to a source region of a field effect transistor. The term “first conductivity type” refers to either “p-type” or “n-type”, and the term “second conductivity type” refers to the other of “p-type” or “n-type” different from the “first conductivity type”.

In the following description, “provided in common” means that an element is provided to be shared by a plurality of some other elements, in other words, the element is shared by a predetermined number of the some other elements, unless otherwise specified.

Hereinafter, modes for carrying out the present disclosure will be described in detail with reference to the drawings. The description will be given in the following order.
1. Background to creation of embodiments of present disclosure by inventors
1.1 Circuit configuration of pixel 10
1.2 Configuration example of photodetector 501
1.3 Configuration example of distance measurement system 611
1.4 Detailed configuration of pixel 10 according to Comparative Example
1.5 Background
2. First embodiment
2.1 Configuration of section
2.2 Configuration of plane
2.3 Modification
3. Second embodiment
3.1 Configuration of plane
3.2 Modification
4. Third embodiment
4.1 Configuration of section
4.2 Configuration of plane
5. Fourth embodiment
5.1 Detailed configuration
5.2 Modification
6. Fifth embodiment
7. Sixth embodiment
8. Seventh embodiment
8.1 Detailed configuration
8.2 Modification
9. Eighth embodiment
9.1 Detailed configuration
9.2 Modification
10. Ninth embodiment
10.1 Detailed configuration
10.2 Modification
11. Tenth embodiment
11.1 Detailed configuration
11.2 Modification
12. Eleventh embodiment
12.1 Production method
12.2 Modification
13. Conclusion
14. Application Example
15. Supplement

### 1. Background to Creation of Embodiments of Present Disclosure by Inventors

### 1.1 Circuit Configuration of Pixel 10

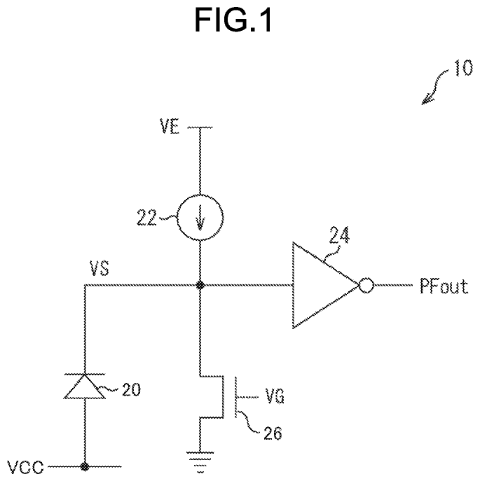

First, prior to a detailed description of an embodiment of the present disclosure, an example of a circuit configuration of a pixel 10 to which the embodiment of the present disclosure may be applied will be described with reference to FIG. 1. FIG. 1 is an explanatory diagram for explaining an example of a circuit configuration of the pixel 10. Specifically, FIG. 1 illustrates a circuit configuration of the pixel 10 including a photodiode (light receiving element) 20 having a single photon avalanche diode (SPAD) structure applicable to a distance measurement sensor that measures distances through a direct time-of-flight (ToF) method.

As illustrated in FIG. 1, the pixel 10 includes the photodiode 20, a constant current source 22, an inverter 24, and a transistor 26.

As described earlier, the photodiode 20 has a SPAD structure and can operate at a bias voltage larger than a breakdown voltage VBD (Geiger mode). The photodiode 20 is an element that can detect single particles of light (photons) for each pixel 10 by multiplying electrons (charges) generated by photoelectric conversion in a PN junction region of a high electric field provided for each pixel 10. In detail, the photodiode 20 is a photodiode (single-photon avalanche photodiode) that causes avalanche amplification of electrons (charges) generated by incident light and outputs a signal voltage VS obtained by the amplification to the inverter 24. The photodiode 20 includes a cathode electrically connected to the constant current source 22, an input terminal of the inverter 24, and a drain of the transistor 26. The photodiode 20 further includes an anode electrically connected to a power supply. For example, a voltage larger than the breakdown voltage VBD of the photodiode 20 (hereinafter, the voltage is referred to as excess bias) is applied to the photodiode 20 to efficiently detect light (photons). A power supply voltage VCC supplied to the anode of the photodiode 20 is, for example, a negative bias (negative potential) having the same voltage as the breakdown voltage VBD of the photodiode 20.

The constant current source 22 includes, for example, a p-type metal oxide semiconductor (MOS) transistor operating in a saturation region, and performs passive quenching by acting as a quenching resistor. A power supply voltage VE is supplied to the constant current source 22. A pull-up resistor or the like may be used for the constant current source 22 instead of the p-type MOS transistor.

The drain of the transistor 26 is connected to the cathode of the photodiode 20, the input terminal of the inverter 24, and the constant current source 22, and the source of the transistor 26 is connected to a ground (GND). A control signal is supplied to the gate of the transistor 26 from a pixel drive unit (not illustrated) that drives the pixel 10. Specifically, when the pixel 10 is an effective pixel, a low (Lo) control signal is supplied from the pixel drive unit to the gate of the transistor 26. When the pixel 10 is not an effective pixel, a high (Hi) control signal is supplied from the pixel drive unit to the gate of the transistor 26. Here, an effective pixel is a pixel in a state in which light can be detected, and a pixel that is not an effective pixel means a pixel that does not detect light.

The inverter 24 outputs a Hi signal PFₒᵤₜ when the voltage VS from the cathode of the photodiode 20 as an input signal is Lo, and outputs a Lo signal PFₒᵤₜ when the voltage VS from the cathode is Hi.

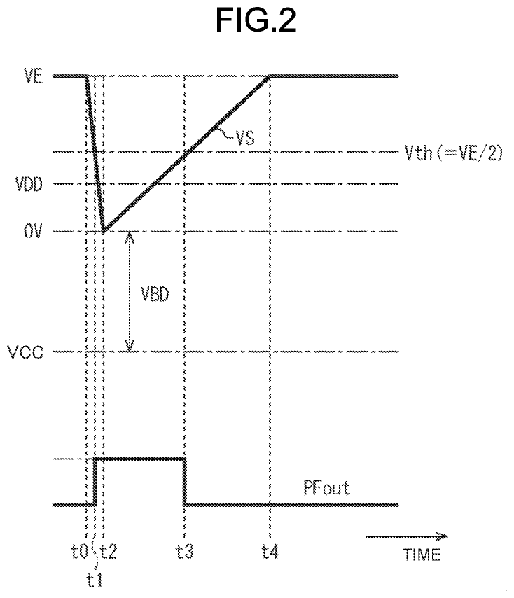

Next, an operation of the pixel 10 as an effective pixel will be described with reference to FIG. 2. FIG. 2 is a graph illustrating a change in a cathode voltage VS of the photodiode 20 and a detection signal PFₒᵤₜ according to incidence of light.

First, when the pixel 10 is an effective pixel, the transistor 26 is set to OFF by a control signal of Lo. At a time before time to, the power supply voltage VE is supplied to the cathode of the photodiode 20, and the power supply VCC is supplied to the anode. Thus, when a reverse voltage larger than the breakdown voltage VBD is applied to the photodiode 20, the photodiode 20 is set to Geiger mode. In this state, the cathode voltage VS of the photodiode 20 is the same as the power supply voltage VE.

When light enters the photodiode 20 set in Geiger mode, avalanche multiplication occurs, and a current flows through the photodiode 20. Specifically, when avalanche multiplication occurs and a current flows through the photodiode 20 at time t0, the current also flows through the p-type MOS transistor serving as the constant current source 22, and a voltage drop occurs because of a resistance component of the MOS transistor.

When the cathode voltage VS of the photodiode 20 becomes lower than 0 V, a reverse voltage smaller than the breakdown voltage VBD is applied to the photodiode 20, and the avalanche amplification stops. Here, an operation in which the current generated by the avalanche amplification flows through the constant current source 22 to generate a voltage drop, and the cathode voltage VS becomes lower than 0 V with the generated voltage drop to stop the avalanche amplification is referred to as a quenching operation.

Then, when the avalanche amplification is stopped at time t2, the current flowing through the constant current source 22 gradually decreases, the cathode voltage VS recovers to the original power supply voltage VE again at time t4, then the photodiode 20 can newly detect light (recharge operation).

For example, the inverter 24 outputs a PFₒᵤₜ signal of Low (Lo) when the cathode voltage VS as an input voltage is equal to or higher than a predetermined threshold voltage Vth (=VE/2), and outputs a PFₒᵤₜ signal of Hi when the cathode voltage VS is lower than the predetermined threshold voltage Vth. In the example illustrated in FIG. 2, a high (Hi) PFₒᵤₜ signal is output during the period from time t1 to time t3.

When the pixel 10 is not an effective pixel, a Hi control signal is supplied from the pixel drive unit (not illustrated) to the gate of the transistor 26, and the transistor 26 is turned on. This causes the cathode voltage VS of the photodiode 20 to be 0 V (GND) and the anode-cathode voltage of the photodiode 20 to be equal to or lower than the breakdown voltage VBD, thus no current is generated with light entering the photodiode 20.

### 1.2 Configuration Example of Photodetector 501

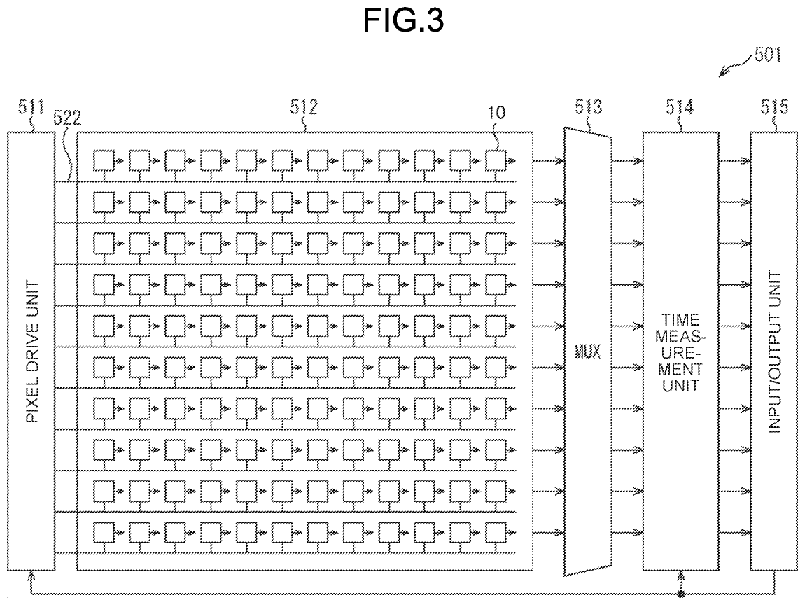

The above-described pixel 10 may be applied to a pixel of a photodetector 501 illustrated in FIG. 3, for example. FIG. 3 is a block diagram illustrating a configuration example of the photodetector 501.

As illustrated in FIG. 3, the photodetector 501 includes a pixel drive unit 511, a pixel array unit 512, a multiplexer (MUX) 513, a time measurement unit 514, and an input/output unit 515, for example. Hereinafter, details of each block included in the photodetector 501 will be sequentially described.

(Pixel Drive Unit 511)

In the pixel array unit 512 described later, pixels 10 are arranged in a matrix, and a pixel drive line 522 is wired along the horizontal direction for each row of the pixels 10. The pixel drive unit 511 drives each pixel 521 by supplying a predetermined drive signal to each pixel 521 via the pixel drive line 522. Specifically, the pixel drive unit 511 can perform a control to set some of the plurality of pixels 10 two-dimensionally arranged in a matrix as effective pixels at a timing according to a light emission timing signal supplied from the outside via the input/output unit 515 described later.

(Pixel Array Unit 512)

The pixel array unit 512 has a configuration in which the pixels 10 that detect light and output a detection signal PFₒᵤₜ indicating a detection result as a pixel signal are two-dimensionally arranged in a matrix in a row direction and a column direction. The number of rows and the number of columns of the pixels 10 of the pixel array unit 512 are not limited to the number illustrated in FIG. 3. As described above, the pixel drive line 522 is wired along the horizontal direction for each pixel row with respect to the matrix-like pixel array of the pixel array unit 512. The pixel drive line 522 is illustrated as one wiring, but it may be configured by a plurality of wirings. One end of the pixel drive line 522 is connected to an output end corresponding to each pixel row of the pixel drive unit 511.

(MUX513)

The MUX 513 can select an output from an effective pixel according to switching between the effective pixel and the non-effective pixel in the pixel array unit 512 and output a pixel signal input from the selected effective pixel to the time measurement unit 514 described below.

(Time Measurement Unit 514)

Based on the pixel signal of the effective pixel supplied from the MUX 513 and the light emission timing signal indicating the light emission timing of the light emission source (not illustrated), the time measurement unit 514 generates a count value corresponding to the time from when the light emission source emits light to when the effective pixel detects the light. The light emission timing signal is supplied from the outside via the input/output unit 515 described below.

(Input/Output Unit 515)

The input/output unit 515 outputs the count value of the effective pixel supplied from the time measurement unit 514 to the outside as a pixel signal. Furthermore, the input/output unit 515 supplies the light emission timing signal supplied from the outside to the pixel drive unit 511 and the time measurement unit 514.

### 1.3 Configuration Example of Distance Measurement System 611

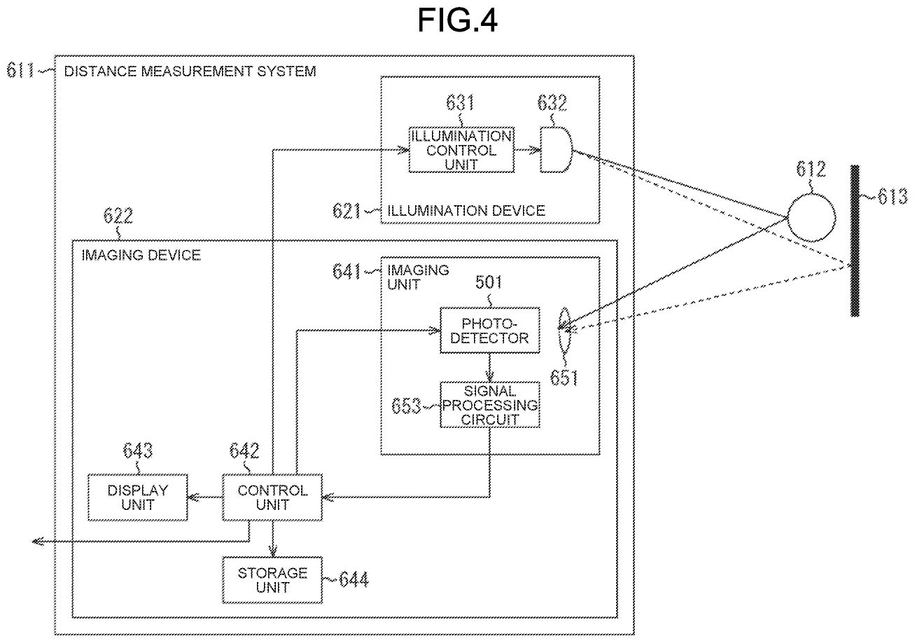

The above-described photodetector 501 may be applied to the distance measurement system 611 illustrated in FIG. 4, for example. FIG. 4 is a block diagram illustrating a configuration example of the distance measurement system 611 incorporating the photodetector 501. The distance measurement system 611 is a system that captures a distance image using the ToF method, for example. Here, the distance image is an image including a distance pixel signal based on a distance detected for each pixel in a depth direction from the distance measurement system 611 to a subject.

As illustrated in FIG. 4, the distance measurement system 611 includes an illumination device 621 and an imaging device 622. Hereinafter, details of each block included in the distance measurement system 611 will be sequentially described.

(Illumination Device 621)

As illustrated in FIG. 4, the illumination device 621 includes an illumination control unit 631 and a light source 632. The illumination control unit 631 controls a pattern for emitting light from the light source 632 under the control of a control unit 642 of the imaging device 622. Specifically, the illumination control unit 631 controls the pattern for emitting light from the light source 632 according to an irradiation code included in an irradiation signal supplied from the control unit 642. For example, the irradiation code has two values of 1 (High) and 0 (Low), and the illumination control unit 631 turns on the light source 632 when the value of the irradiation code is 1 and turns off the light source 632 when the value of the irradiation code is 0.

The light source 632 emits light in a predetermined wavelength region under the control of the illumination control unit 631. The light source 632 may be made of, for example, an infrared laser diode. The type of the light source 632 and the wavelength range of the irradiation light may be freely set according to the application or the like of the distance measurement system 611.

(Imaging Device 622)

The imaging device 622 is a device that receives reflected light obtained by reflecting light (irradiation light) emitted from the illumination device 621 by a subject 612, a subject 613, and the like. As illustrated in FIG. 4, the imaging device 622 includes an imaging unit 641, the control unit 642, a display unit 643, and a storage unit 644.

In detail, as illustrated in FIG. 4, the imaging unit 641 includes a lens 651, a signal processing circuit 653, and the photodetector 501. The lens 651 can form an image of incident light on a light receiving surface of the photodetector 501. The lens 651 may take any configuration, and for example, the lens 651 may be configured by a plurality of lens groups.

As the photodetector 501, the photodetector 501 described above may be applied. Under the control of the control unit 642, the photodetector 501 receives reflected light from the subject 612, the subject 613, and the like, and supplies a pixel signal obtained as a result to the signal processing circuit 653. The pixel signal indicates a digital count value obtained by counting the time from when the illumination device 621 emits irradiation light to when the photodetector 501 receives the irradiation light. The light emission timing signal indicating the timing at which the light source 632 emits light is supplied from the control unit 642 to the photodetector 501.

The signal processing circuit 653 processes the pixel signal supplied from the photodetector 501 under the control of the control unit 642. For example, the signal processing circuit 653 detects the distance to the subjects 612, 613 for each pixel based on the pixel signal supplied from the photodetector 501, and generates a distance image indicating the distance to the subjects 612, 613 for each pixel 10. Specifically, the signal processing circuit 653 acquires the time (count value) from when the light source 632 emits light to when each pixel 10 of the photodetector 501 receives the light a plurality of times (for example, several thousands to several tens of thousands of times) for each pixel 10. The signal processing circuit 653 creates a histogram corresponding to the acquired time. Then, by detecting the peak of the histogram, the signal processing circuit 653 determines the time until the light emitted from the light source 632 is reflected by the subject 612 or the subject 613 and returns. Further, the signal processing circuit 653 performs calculation to obtain the distance to the subjects 612, 613 based on the determined time and light speed. The signal processing circuit 653 supplies the generated distance image to the control unit 642.

The control unit 642 is composed of a control circuit such as a field programmable gate array (FPGA) or a digital signal processor (DSP), a processor, and the like, for example. The control unit 642 controls the illumination control unit 631 and the photodetector 501. Specifically, the control unit 642 supplies an irradiation signal to the illumination control unit 631 and supplies a light emission timing signal to the photodetector 501. The light source 632 emits irradiation light according to the irradiation signal. The light emission timing signal may be the irradiation signal supplied to the illumination control unit 631. The control unit 642 supplies the distance image acquired from the imaging unit 641 to the display unit 643 and causes the display unit 643 to display the distance image. Further, the control unit 642 stores the distance image acquired from the imaging unit 641 in the storage unit 644. The control unit 642 outputs the distance image acquired from the imaging unit 641 to the outside.

The display unit 643 is composed of, for example, a panel type display device such as a liquid crystal display device or an organic electro luminescence (EL) display device.

The storage unit 644 may be composed of any storage device, a storage medium, or the like, and stores the distance image or the like.

### 1.4 Detailed Configuration of Pixel 10 According to Comparative Example

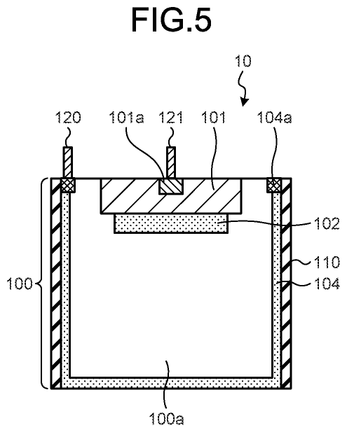

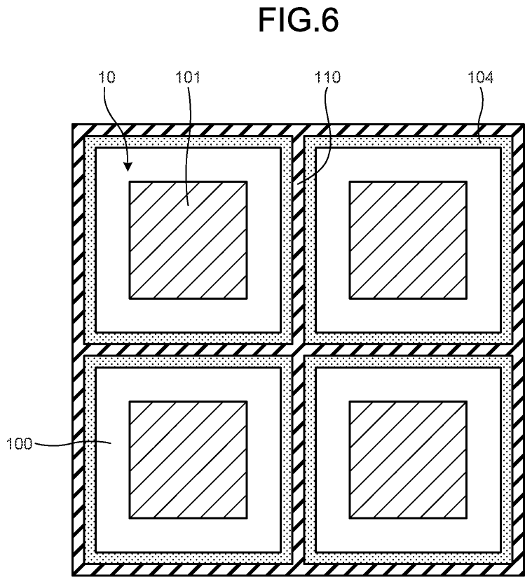

Next, an example of a detailed configuration of a pixel 10 according to Comparative Example to be compared with the embodiments of the present disclosure will be described with reference to FIGS. 5 and 6. FIG. 5 is a schematic sectional view illustrating an example of a detailed configuration of the pixel 10 according to Comparative Example. In FIG. 5, the positional relationship of the components is schematically illustrated for easy understanding and, the section may be different from an actual section. FIG. 6 is a schematic plan view illustrating an example of a detailed configuration of the pixel 10 according to Comparative Example, and specifically illustrates a plane in which four pixels 10 are arranged in a matrix. Here, Comparative Example means the pixel 10 that has been repeatedly studied by the inventors of the present disclosure before the embodiments of the present disclosure are made.

In the following description, it is assumed that the pixel 10 is a back-illuminated pixel on which light is incident from the lower surface (back surface) side in FIG. 5. However, the pixel 10 is not limited to the back-illuminated pixel, and it may be a front-illuminated pixel 10 on which light is incident via a wiring layer (not illustrated) provided on the front surface of a semiconductor substrate.

In detail, in the sectional view of the pixel 10 illustrated in FIG. 5, a structure mainly related to a semiconductor substrate 100 is illustrated, in which the lower side of FIG. 5 is the back surface side of the semiconductor substrate 100, and an on-chip lens (not illustrated) or the like is formed on the back surface. The back surface is a light receiving surface for reflected light reflected from a subject to enter. The upper side of FIG. 5 is the front surface side of the semiconductor substrate 100, and although not illustrated, a wiring layer including a circuit or the like that drives the pixel 10 is formed.

As illustrated in FIG. 5, the pixel 10 includes an n-well region 100a, an n-type semiconductor region 101, a high-concentration n-type semiconductor region 101a, a p-type semiconductor region 102, a hole accumulation region 104, and a high-concentration p-type semiconductor region 104a provided in the semiconductor substrate 100 made of a silicon substrate. The pixel 10 has a pixel isolation unit 110 that surrounds the pixel 10 and isolates the pixel from another adjacent pixel 10. The pixel 10 further includes an anode electrode 120 electrically connected to the high-concentration p-type semiconductor region 104a and a cathode electrode 121 electrically connected to the high-concentration n-type semiconductor region 101a.

The n-well region 100a is a region having a low impurity concentration in the semiconductor substrate 100 having an n-type conductivity type, and generates an electric field that transfers electrons generated by photoelectric conversion to an avalanche multiplication region to be described later.

The p-type semiconductor region 102 and the n-type semiconductor region 101 are configured to form a PN junction on the n-well region 100a. The above-described avalanche multiplication region is formed by a depletion layer generated in the region where the p-type semiconductor region 102 and the n-type semiconductor region 101 are joined. For example, the impurity concentration of the n-well region 100a is preferably set to a low concentration of 1E+14/cm³ or less. This can improve light detection efficiency called photon detection efficiency (PDE). For example, the impurity concentration of each of the n-type semiconductor region 101 and the p-type semiconductor region 102 forming the avalanche multiplication region is preferably a high concentration of 1E+16/cm³ or more.

The n-type semiconductor region 101 has, at the upper center thereof, the high-concentration n-type semiconductor region 101a, which is a thick n-type semiconductor region formed at a predetermined depth from the front surface side of the semiconductor substrate 100. The high-concentration n-type semiconductor region 101a is a contact unit connected to the cathode electrode 121 for supplying a positive voltage for forming the avalanche multiplication region. Thus, the power supply voltage VE is applied from the cathode electrode 121 to the high-concentration n-type semiconductor region 101a.

The hole accumulation region 104 is a p-type semiconductor region formed to surround the side surface and the bottom surface of the n-well region 100a, and it can accumulate holes generated by photoelectric conversion. The hole accumulation region 104 also has an effect of trapping electrons generated at the interface with the pixel isolation unit 110 to be described later and reducing dark count rate (DCR). Providing the hole accumulation region 104 on the side surface of the n-well region 100a causes a lateral electric field to form, more charges to be collected in the high electric field region, and the PDE to improve.

The high-concentration p-type semiconductor region 104a having a high impurity concentration is provided in a region near the front surface of the semiconductor substrate 100 in the hole accumulation region 104. The high-concentration p-type semiconductor region 104a is a contact unit connected to the anode electrode 120. Thus, the power supply voltage VCC is applied from the anode electrode 120 to the high-concentration p-type semiconductor region 104a.

The pixel isolation unit 110 that isolates pixels 10 from each other is provided at a pixel boundary part of the pixel 10 which is a boundary with adjacent pixels. For example, the pixel isolation unit 110 may be formed only of an insulating layer such as a silicon oxide film, or may have a double structure in which the outer side (n-well region 100a side) of a metal layer such as tungsten is covered with an insulating layer such as a silicon oxide film. Providing the pixel isolation unit 110 and the hole accumulation region 104 can reduce electrical and optical crosstalk between the pixels 10.

Next, FIG. 6 illustrates a state in which four pixels 10 of 2×2 are arranged when the semiconductor substrate 100 is viewed from above the front surface. The high-concentration p-type semiconductor region 104a, the anode electrode 120, and the cathode electrode 121 are not illustrated in FIG. 6. As described above, each pixel 10 is isolated by the pixel isolation unit 110 formed in a grid. The hole accumulation region 104 electrically connected to the anode electrode 120 via the high-concentration p-type semiconductor region 104a is provided along the pixel isolation unit 110 on the inner side of each pixel isolation unit 110. Further, the n-type semiconductor region 101 electrically connected to the cathode electrode 121 via the high-concentration n-type semiconductor region 101a is provided at the center of each pixel 10.

The pixel 10 has been described as having a structure of reading out electrons as signal charges (charges), but the pixel 10 is not limited to this structure and may have a structure of reading out holes. In such a case, each semiconductor region of the pixel 10 has an inverted conductivity type of the above-described conductivity type.

### 1.5 Background

Next, details of the background in which the inventors of the present disclosure have created the embodiments of the present disclosure will be described with reference to FIG. 5 based the above-described configuration of the pixel 10. In the pixel 10 according to Comparative Example described above, the distance between the anode electrode 120 and the cathode electrode 121 becomes shorter as the size of the pixel 10 becomes smaller. In other words, the distance between the n-type semiconductor region 101 that forms the avalanche multiplication region and the high-concentration p-type semiconductor region 104a that is a contact unit of the anode electrode 120 and contains a high-concentration p-type conductive impurity having conductivity opposite to that of the n-type semiconductor region 101 is shortened. Since the distance is shortened as described above, electric field concentration occurs, and the withstand voltage of the pixel 10 decreases. Since the withstand voltage decreases, occurrence of defects such as breaking of the pixel 10 increases. On the other hand, when the distance is secured to secure a predetermined withstand voltage, there is a limit to miniaturizing the size of the pixel 10. Thus, it has been difficult to further miniaturize the pixel 10.

In view of the above-described situation, the inventors of the present disclosure have intensively studied a structure of the pixel 10 that can be further miniaturized while securing a desired withstand voltage, and have created a first embodiment of the present disclosure described below. In the pixel 10 according to Comparative Example, when the semiconductor substrate 100 is viewed from above the front surface, the n-type semiconductor region 101 electrically connected to the cathode electrode 121 is provided at the center of the pixel 10, that is, the n-type semiconductor region 101 is provided in a point-symmetrical manner with respect to the center point of the pixel 10. On the other hand, in the pixel 10 according to the first embodiment of the present disclosure created by the inventors of the present disclosure, the n-type semiconductor region 101 is provided in an asymmetric manner with respect to the center point of the pixel 10. In detail, in Comparative Example and the present embodiment, the cathode electrode 121 to be electrically connected is provided at the upper center of the n-type semiconductor region 101. Further, in Comparative Example and the present embodiment, the anode electrode 120 is provided to be electrically connected to a region near the front surface of the semiconductor substrate 100 in the hole accumulation region 104 provided to cover the side surface of the n-well region 100a. However, in the present embodiment, the n-type semiconductor region 101 is provided such that the center point of the n-type semiconductor region 101 is farther from the anode electrode 120 than the center point of the pixel 10, in other words, the n-type semiconductor region 101 is provided in an asymmetrical manner with respect to the center point of the pixel 10. Thus, in the present embodiment, as compared with Comparative Example including pixels 10 having the same size, the distance between the anode electrode 120 and the cathode electrode 121, in other words, the distance between the n-type semiconductor region 101 forming the avalanche multiplication region and the high-concentration p-type semiconductor region 104a is long. As a result, according to the present embodiment, since the electric field concentration can be alleviated, it is possible to avoid the withstand voltage of the pixel 10 from decreasing. Hereinafter, details of such a first embodiment of the present disclosure will be sequentially described.

### 2. First Embodiment

### 2.1 Configuration of Section

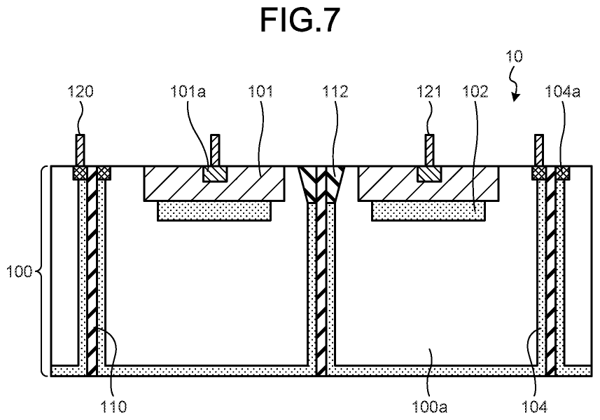

First, a configuration of a section the pixel 10 according to the first embodiment of the present disclosure created by the inventors of the present disclosure will be described in detail with reference to FIG. 7. FIG. 7 is a schematic sectional view illustrating an example of a detailed configuration of the pixel 10 according to the present embodiment. In detail, in the sectional view of the pixel 10 illustrated in FIG. 7, a state in which two pixels 10 are arranged is illustrated. The lower side of FIG. 7 is the back surface side of the semiconductor substrate 100. An on-chip lens (not illustrated) or the like is formed on the back surface, and the back surface is the light receiving surface for reflected light reflected from a subject to enter. The upper side of FIG. 7 is the front surface side of the semiconductor substrate 100.

As illustrated in FIG. 7, the pixel (light receiving element) 10 according to the present embodiment includes an n-well region (photoelectric conversion unit) 100a, an n-type semiconductor region 101, a high-concentration n-type semiconductor region 101a, a p-type semiconductor region 102, a hole accumulation region 104, and a high-concentration p-type semiconductor region 104a provided in the semiconductor substrate 100 formed of a silicon substrate of an n-type conductivity type. The pixel 10 has a pixel isolation unit (pixel isolation wall) 110 that surrounds the pixel 10 and isolates the pixel from another adjacent pixel 10. The pixel 10 further includes an anode electrode (anode unit) 120 electrically connected to the high-concentration p-type semiconductor region 104a and a cathode electrode (cathode unit) 121 electrically connected to the high-concentration n-type semiconductor region 101a.

The n-well region 100a is a region having a low impurity concentration in the semiconductor substrate 100 of an n-type conductivity type, and generates an electric field that transfers electrons (charges) generated by photoelectric conversion of light incident from the light receiving surface of the semiconductor substrate to an avalanche multiplication region.

On the n-well region 100a, the p-type semiconductor region (first semiconductor region) 102 having a p-type conductivity type (first conductivity type) and an n-type semiconductor region (second semiconductor region) 101 having an n-type conductivity type (second conductivity type) are configured to form a PN junction. The avalanche multiplication region that amplifies electrons (charges) through photoelectric conversion is formed by a depletion layer generated in the region where the p-type semiconductor region 102 and the n-type semiconductor region 101 are joined. For example, the impurity concentration of the n-well region 100a is preferably set to a low concentration of 1E+14/cm³ or less. This can improve light detection efficiency called photon detection efficiency (PDE). For example, the impurity concentration of each of the n-type semiconductor region 101 and the p-type semiconductor region 102 forming the avalanche multiplication region is preferably a high concentration of 1E+16/cm³ or more.

The n-type semiconductor region 101 has, at the upper center thereof, the high-concentration n-type semiconductor region 101a, which is a thick n-type semiconductor region formed at a predetermined depth from the front surface side of the semiconductor substrate 100. The high-concentration n-type semiconductor region 101a is a contact unit connected to the cathode electrode (cathode unit) 121 for supplying a positive voltage for forming the avalanche multiplication region. The cathode electrode 121 is provided on the high-concentration n-type semiconductor region 101a (surface opposite to the light receiving surface), and the power supply voltage VE is applied to the cathode electrode 121. The cathode electrode 121 and the high-concentration n-type semiconductor region 101a are preferably provided at the center of the n-type semiconductor region 101 so that an electric field is uniformly applied to the n-type semiconductor region 101 and the avalanche multiplication region is uniformly formed.

In the pixel 10 according to the present embodiment, the avalanche multiplication region formed by the p-type semiconductor region 102 and the n-type semiconductor region 101 is not located at the center of the pixel 10, but is provided in an asymmetrical manner with respect to the center point of the pixel 10. In detail, the avalanche multiplication region formed by the p-type semiconductor region 102 and the n-type semiconductor region 101 is formed close to the pixel isolation unit 110 in contact with the hole accumulation region 104 where the anode electrode 120 is not provided. Thus, in the present embodiment, the distance between the anode electrode 120 and the cathode electrode 121, in other words, the distance between the n-type semiconductor region 101 forming the avalanche multiplication region and the high-concentration p-type semiconductor region 104a is long. As a result, according to the present embodiment, since the electric field concentration can be alleviated, it is possible to avoid the withstand voltage of the pixel 10 from decreasing. In the present embodiment, the n-type semiconductor region 101 forming the avalanche multiplication region is preferably far from the high-concentration p-type semiconductor region 104a containing a high-concentration p-type conductive impurity having conductivity opposite to that of the n-type semiconductor region 101. In other words, in the present embodiment, the n-type semiconductor region 101 is preferably close to the pixel isolation unit 110 in contact with the hole accumulation region 104 where the anode electrode 120 is not provided. However, in the present embodiment, it is also conceivable that the electric fields adversely affect each other in the adjacent pixels 10 via the pixel isolation unit 110 in contact with the hole accumulation region 104 in which the anode electrode 120 is not provided. Thus, the n-type semiconductor region 101 is preferably close to the pixel isolation unit 110 in contact with the hole accumulation region 104 in which the anode electrode 120 is not provided as long as such an adverse effect is not exerted.

The hole accumulation region 104 is a p-type semiconductor region formed to surround the outer surface and the bottom surface of the n-well region 100a and can accumulate holes generated by photoelectric conversion. In other words, the hole accumulation region 104 is provided to cover the side surface not having the pixel isolation unit (pixel isolation wall) 110. The hole accumulation region 104 also has an effect of trapping electrons generated at the interface with the pixel isolation unit 110 and reducing DCR. Providing the hole accumulation region 104 on the side surface of the n-well region 100a causes a lateral electric field to form, more charges to be collected in the high electric field region, and the PDE to improve.

The high-concentration p-type semiconductor region 104a having a high impurity concentration is provided in a region near the front surface of the semiconductor substrate 100 in the hole accumulation region 104. The high-concentration p-type semiconductor region 104a is a contact unit connected to the anode electrode (anode unit) 120. The anode electrode 120 is provided on the high-concentration p-type semiconductor region 104a (surface opposite to the light receiving surface), and the power supply voltage VCC is applied to the anode electrode 120.

The pixel isolation unit (pixel isolation wall) 110 that isolates pixels 10 from each other is provided at a pixel boundary part of the pixel 10 which is a boundary with adjacent pixels 10. In other words, the pixel isolation unit 110 is provided to surround the pixel 10 and to penetrate the semiconductor substrate 100 along the film thickness direction of the semiconductor substrate 100. For example, the pixel isolation unit 110 may be formed only of an insulating layer such as a silicon oxide film, or may have a double structure in which the outer side (n-well region 100a side) of a metal layer such as tungsten is covered with an insulating layer such as a silicon oxide film. Providing the pixel isolation unit 110 and the hole accumulation region 104 can reduce electrical and optical crosstalk between the pixels 10.

In the present embodiment, the pixel 10 further includes an isolation oxide film (oxide film) 112 that isolates adjacent pixels 10. In detail, in the present embodiment, the isolation oxide film 112 of a shallow trench isolation (STI) structure having an oxide film (for example, a silicon oxide film) embedded in a groove provided near the front surface of the semiconductor substrate 100 is provided on the front surface (surface opposite to the light receiving surface) side of the semiconductor substrate 100, on the hole accumulation region 104 where no anode electrode 120 is provided. The depth of the isolation oxide film 112 is preferably and substantially equal to the depth of the n-type semiconductor region 101 forming the avalanche multiplication region from the viewpoint of improving the breakdown voltage, and is preferably above the position of the p-type semiconductor region 102 forming the avalanche multiplication region from the viewpoint of reducing generation of dark current. In the present embodiment, providing such an isolation oxide film 112 can reduce occurrence of crosstalk (color mixture) between the pixels 10. Further, in the present embodiment, providing such an isolation oxide film 112 can avoid the impurity having p-type conductivity included in the hole accumulation region 104 from being present near the n-type semiconductor region 101, and thus, it is possible to alleviate the electric field concentration and to avoid the withstand voltage of the pixel 10 from decreasing.

### 2.2 Configuration of Plane

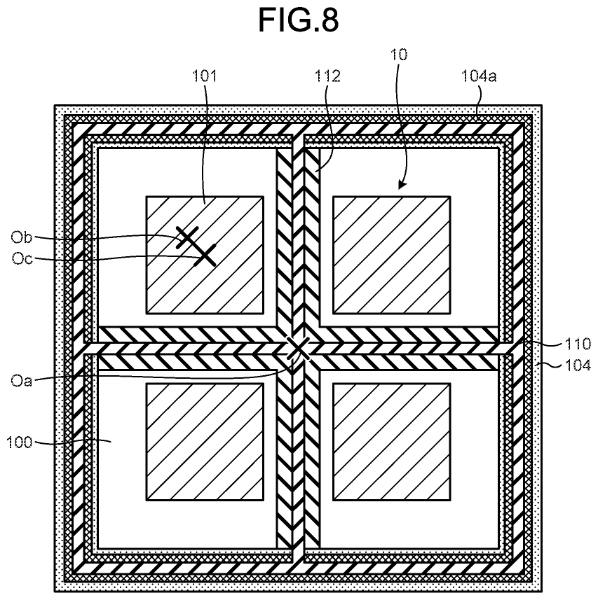

Next, details of a configuration of a plane of the pixel 10 according to the first embodiment of the present disclosure created by the inventors of the present disclosure will be described with reference to FIG. 8. FIG. 8 is a schematic plan view illustrating an example of the detailed configuration of the pixel 10 according to the present embodiment. In detail, FIG. 8 illustrates a state in which four pixels 10 of 2×2 are arranged when the semiconductor substrate 100 is viewed from above the front surface. The anode electrode 120 and the cathode electrode 121 are not illustrated in FIG. 8.

As illustrated in FIG. 8, pixels 10 are arranged in a matrix form in 2×2 in the semiconductor substrate 100 (pixel group). Each pixel 10 is isolated from each other by the pixel isolation unit 110 formed in a grid and surrounding each pixel 10. The hole accumulation region 104 electrically connected to the anode electrode 120 via the high-concentration p-type semiconductor region 104a is provided along the pixel isolation unit 110 on the inner side of each pixel isolation unit 110.

Further, as illustrated in FIG. 8, each pixel 10 is provided with the n-type semiconductor region 101 electrically connected to the cathode electrode 121 via the high-concentration n-type semiconductor region 101a. In detail, the n-type semiconductor region 101 is provided such that a center point Oc of the n-type semiconductor region 101 is farther from the anode electrode 120 than a center point Ob of the pixel 10. In other words, the n-type semiconductor region 101 is provided such that the center point Oc of the n-type semiconductor region 101 is closer to a center point Oa of the pixel group composed of 2×2 of pixels 10 than the center point Ob of the corresponding pixel 10. In the present embodiment, the n-type semiconductor region 101 forming the avalanche multiplication region is preferably far from the high-concentration p-type semiconductor region 104a containing a p-type conductive impurity having conductivity opposite to that of the n-type semiconductor region 101 at a high concentration, and the distance between the n-type semiconductor region 101 and the high-concentration p-type semiconductor region 104a is preferably adjusted in the adjacent pixels 10 via the pixel isolation unit 110 in contact with the hole accumulation region 104 where the anode electrode 120 is not provided as long as the electric fields of the adjacent pixels 10 do not adversely affect each other.

In the present embodiment, the longer the distance between the anode electrode 120 and the cathode electrode 121 is, the more preferable it is from the viewpoint of securing the withstand voltage of the pixel 10. The cathode electrode 121 and the high-concentration n-type semiconductor region 101a are preferably provided at the center of the n-type semiconductor region 101 so that an electric field is uniformly applied to the n-type semiconductor region 101 and the avalanche multiplication region is uniformly formed. In the present embodiment, for example, the relationship between the distance L (μm) between the anode electrode 120 and the cathode electrode 121 and the applied voltage V is preferably about V/L<40 (V/μm).

Further, in the present embodiment, as illustrated in FIG. 8, the n-type semiconductor region 101 has a substantially rectangular shape. When the n-type semiconductor region 101 is formed in a substantially rectangular shape as illustrated, it is possible to secure a wide area of the avalanche multiplication region and can improve the PDE. In the present embodiment, the shape of the n-type semiconductor region 101 is not limited to particular shapes.

In the present embodiment, the pixel 10 includes the isolation oxide film (first oxide film) 112 provided on the front surface (surface opposite to the light receiving surface) side of the semiconductor substrate 100, on the hole accumulation region 104 located between adjacent pixels 10 where no anode electrode 120 is provided. In the present embodiment, providing such an isolation oxide film 112 can reduce occurrence of crosstalk (color mixture) between the pixels 10, as described earlier. Further, in the present embodiment, providing such an isolation oxide film 112 can avoid the impurity having p-type conductivity included in the hole accumulation region 104 from being present near the n-type semiconductor region 101, and thus, it is possible to alleviate the electric field concentration and to avoid the withstand voltage of the pixel 10 from decreasing.

In the present embodiment, the widths of the hole accumulation region 104 and the isolation oxide film 112 may be substantially equal to each other or may be different from each other.

As described above, in the present embodiment, the distance between the anode electrode 120 and the cathode electrode 121, in other words, the distance between the n-type semiconductor region 101 forming the avalanche multiplication region and the high-concentration p-type semiconductor region 104a is long. As a result, according to the present embodiment, since the electric field concentration can be alleviated, it is possible to avoid the withstand voltage of the pixel 10 from decreasing. Further, according to the present embodiment, the sensitivity of the pixel 10 can further improve since it is possible to increase the size of the avalanche multiplication region formed in the junction region between the p-type semiconductor region 102 and the n-type semiconductor region 101 with a pixel reduced in size.

The pixel 10 according to the present embodiment has been described as having a structure of reading out electrons as signal charges (charges). The pixel 10 is not limited to such a structure but may have a structure of reading out holes. In such a case, each semiconductor region of the pixel 10 has an inverted conductivity type of the above-described conductivity type.

### 2.3 Modification

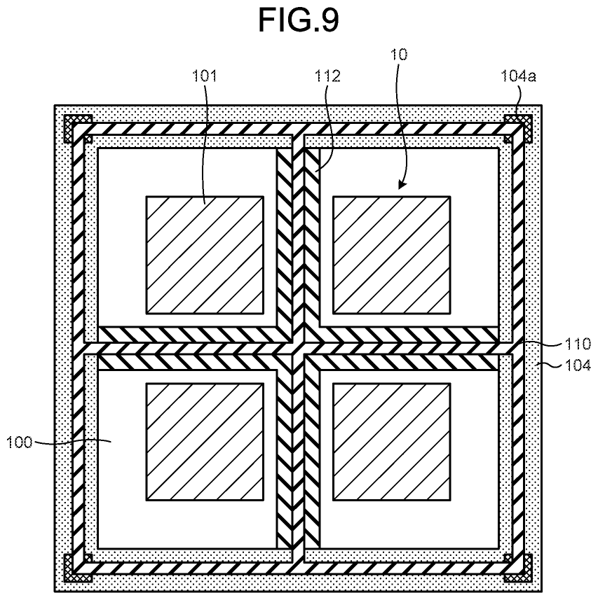

Next, a modification of the present embodiment will be described with reference to FIG. 9. FIG. 9 is a schematic plan view illustrating an example of a detailed configuration of the pixel 10 according to the modification of the present embodiment. In the present modification, as illustrated in FIG. 9, the high-concentration p-type semiconductor region 104a as a contact unit connected to the anode electrode (anode portion) 120 is provided in a region near the front surface (surface on the opposite side to the light receiving surface) of the semiconductor substrate 100 in the hole accumulation region 104 covering the four corners of the pixel isolation unit (pixel isolation wall) 110 surrounding the pixel group composed of a plurality of pixels 10 arranged in a matrix form in 2×2 in the semiconductor substrate 100. In the present modification, providing the high-concentration p-type semiconductor region 104a connected to the anode electrode 120 only at the four corners of the pixel group causes the distance between the n-type semiconductor region 101 forming the avalanche multiplication region and the high-concentration p-type semiconductor region 104a to be long. As a result, according to the present modification, it is possible to alleviate the electric field concentration and avoid the withstand voltage of the pixel 10 from decreasing.

### 3. Second Embodiment

### 3.1 Configuration of Plane

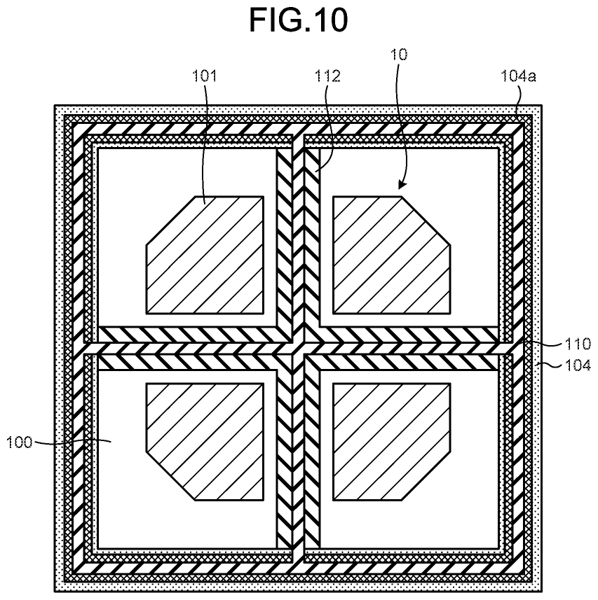

A configuration of a plane of the pixel 10 according to a second embodiment of the present disclosure will be described in detail with reference to FIG. 10. FIG. 10 is a schematic plan view illustrating an example of a detailed configuration of the pixel 10 according to the present embodiment.

In the first embodiment of the present disclosure described above, the n-type semiconductor region 101 has a substantially rectangular shape as illustrated in FIG. 8. In the embodiments of the present disclosure, as illustrated in FIG. 10, the n-type semiconductor region 101 may have a polygonal shape with one of four corners being chamfered. In detail, the chamfered corner among the four corners is the corner close to the high-concentration p-type semiconductor region 104a connected to the anode electrode 120. In the present embodiment, forming the n-type semiconductor region 101 into a polygonal shape with one of the four corners being chamfered as described causes the distance between the n-type semiconductor region 101 forming the avalanche multiplication region and the high-concentration p-type semiconductor region 104a to be long, which makes it possible to alleviate the electric field concentration and to avoid the withstand voltage of the pixel 10 from decreasing.

### 3.2 Modification

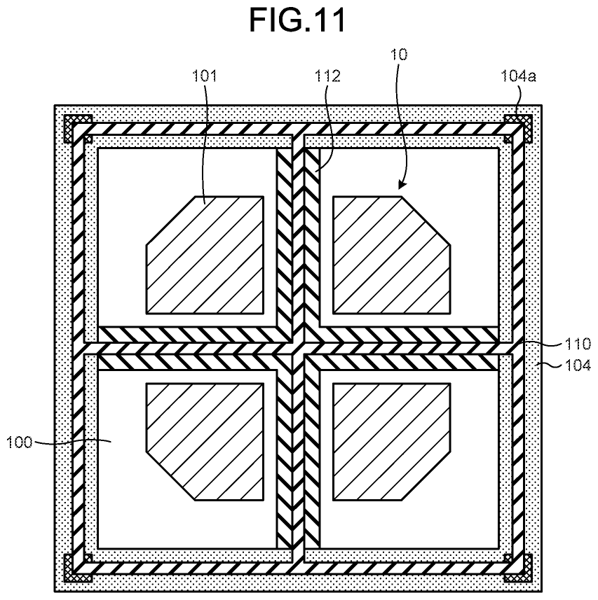

Next, a modification of the present embodiment will be described with reference to FIG. 11. FIG. 11 is a schematic plan view illustrating an example of a detailed configuration of the pixel 10 according to the modification of the present embodiment. In the present modification, similarly to the modification of the first embodiment, the high-concentration p-type semiconductor region 104a connected to the anode electrode 120 is located only at the four corners of the pixel group, which causes the distance between the n-type semiconductor region 101 forming the avalanche multiplication region and the high-concentration p-type semiconductor region 104a to be long. Further, in the present modification, the n-type semiconductor region 101 is formed into a polygonal shape with a corner of the n-type semiconductor region 101 close to the high-concentration p-type semiconductor region 104a connected to the anode electrode 120 being chamfered, which cause the distance between the n-type semiconductor region 101 and the high-concentration p-type semiconductor region 104a to further increase. As a result, according to the present modification, it is possible to alleviate the electric field concentration and further avoid the withstand voltage of the pixel 10 from decreasing.

### 4. Third Embodiment

### 4.1 Configuration of Section

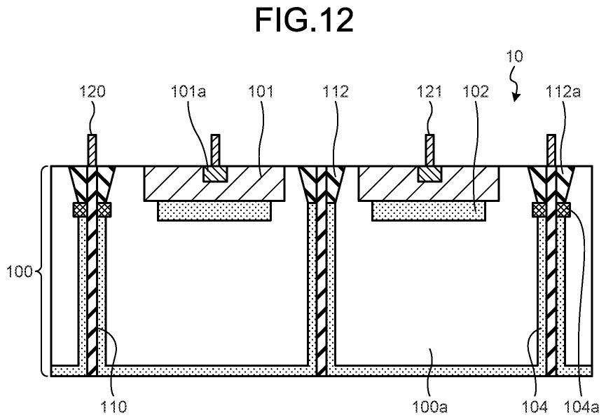

Next, a configuration of a section of the pixel 10 according to the third embodiment of the present disclosure will be described in detail with reference to FIG. 12. FIG. 12 is a schematic sectional view illustrating an example of a detailed configuration of the pixel 10 according to the present embodiment. In the first embodiment described earlier, the isolation oxide film 112 is provided on the front surface side of the semiconductor substrate 100, on the hole accumulation region 104 where no anode electrode 120 is provided. However, the present disclosure is not limited to this, and an isolation oxide film (second oxide film) 112a may be provided on the front surface side of the semiconductor substrate 100, on the hole accumulation region 104 where the anode electrode 120 is provided.

In detail, in the present embodiment, as illustrated in FIG. 12, the isolation oxide film (second oxide film) 112a of an STI structure having an oxide film (for example, a silicon oxide film) embedded in a groove provided near the front surface of the semiconductor substrate 100 is provided on the front surface (surface opposite to the light receiving surface) side of the semiconductor substrate 100, on the hole accumulation region 104 where the anode electrode 120 is provided. The depth of the isolation oxide film 112 a is preferably and substantially equal to the depth of the n-type semiconductor region 101 forming the avalanche multiplication region from the viewpoint of improving the breakdown voltage, and is preferably above the position of the p-type semiconductor region 102 forming the avalanche multiplication region from the viewpoint of reducing occurrence of dark current, similarly to the isolation oxide film 112 described above. In the present embodiment, providing such an isolation oxide film 112a can reduce occurrence of crosstalk (color mixture) between pixels 10. Further, in the present embodiment, providing such an isolation oxide film 112a can avoid the impurity having p-type conductivity included in the hole accumulation region 104 from being present near the n-type semiconductor region 101, and thus, it is possible to alleviate the electric field concentration and to avoid the withstand voltage of the pixel 10 from decreasing.

In the present embodiment, it is preferable to perform ion implantation of impurities on a region to be the high-concentration p-type semiconductor region 104a after the formation of the isolation oxide film 112a to secure electrical connection (ohmic contact) between the anode electrode 120 and the high-concentration p-type semiconductor region 104a via the pixel isolation unit 110.

### 4.2 Configuration of Plane

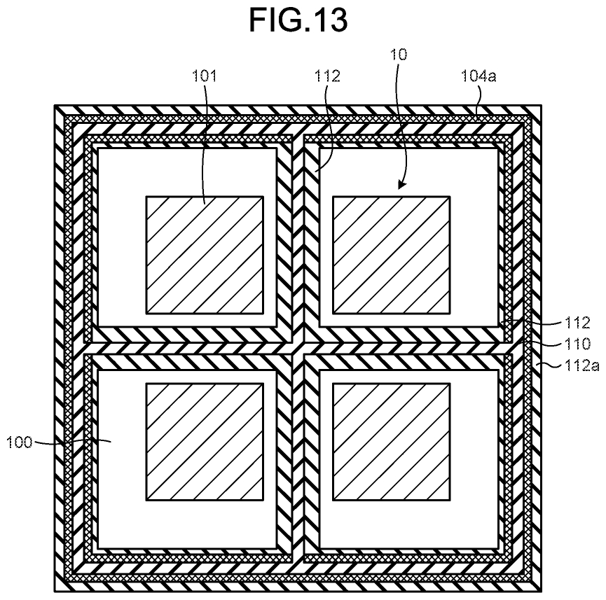

Next, a configuration of a plane of the pixel 10 according to the present embodiment will be described in detail with reference to FIG. 13. FIG. 13 is a schematic plan view illustrating an example of a detailed configuration of the pixel 10 according to the present embodiment.

In the present embodiment, as illustrated in FIG. 13, the pixel 10 includes the isolation oxide film 112a provided on the front surface side of the semiconductor substrate 100, on the hole accumulation region 104 where the anode electrode 120 located to surround the pixel group is provided. In the present embodiment, as described earlier, providing such an isolation oxide film 112a reduces occurrence of crosstalk (color mixture) between pixels 10. Further, in the present embodiment, providing such an isolation oxide film 112a can avoid the impurity having p-type conductivity included in the hole accumulation region 104 from being present near the n-type semiconductor region 101, and thus, it is possible to alleviate the electric field concentration and to avoid the withstand voltage of the pixel 10 from decreasing.

### 5. Fourth Embodiment

### 5.1 Detailed Configuration

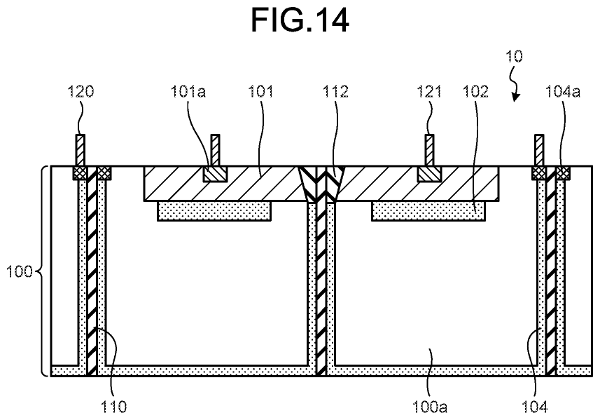

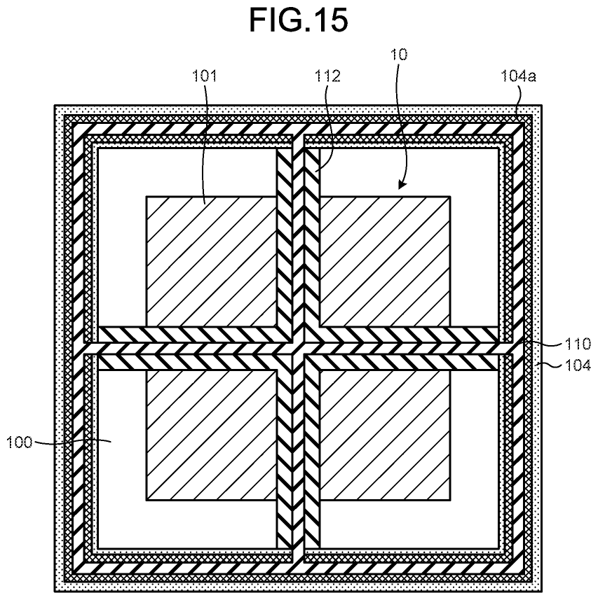

Next, a configuration of a section of the pixel 10 according to the fourth embodiment of the present disclosure will be described in detail with reference to FIGS. 14 and 15. FIG. 14 is a schematic sectional view illustrating an example of a detailed configuration of the pixel 10 according to the present embodiment. FIG. 15 is a schematic plan view illustrating the example of a detailed configuration of the pixel 10 according to the present embodiment.

In each embodiment of the present disclosure described earlier, adjacent pixels 10 in the pixel group are isolated from each other by the isolation oxide film 112 having an STI structure. Thus, with the presence of the isolation oxide film 112, the impurity having an n-type conductivity type located near the front surface of the semiconductor substrate 100, that is, the n-type semiconductor region 101 can be isolated for each pixel 10. In the present embodiment, since the n-type semiconductor region 101 can be isolated for each pixel 10 by the isolation oxide film 112, the n-type semiconductor region 101 can be made wider than the p-type semiconductor region 102.

In detail, as illustrated in FIGS. 14 and 15, the n-type semiconductor region (second semiconductor region) 101 of each pixel 10 in the pixel group is isolated from each other by the isolation oxide film (first oxide film) 112, and the n-type semiconductor region 101 is wider than the p-type semiconductor region (first semiconductor region) 102.

In the present embodiment, as illustrated in FIG. 15, the n-type semiconductor region 101 has a substantially rectangular shape. When the n-type semiconductor region 101 is formed in a substantially rectangular shape as illustrated, it is possible to secure a wide area of the avalanche multiplication region and can improve the PDE.

### 5.2 Modification

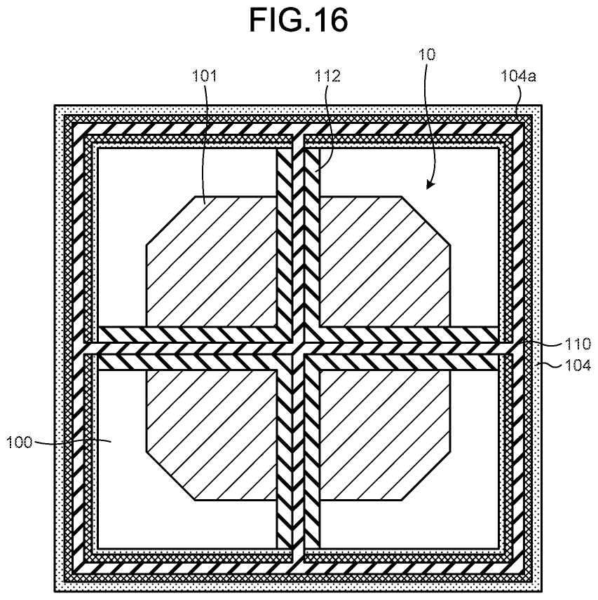

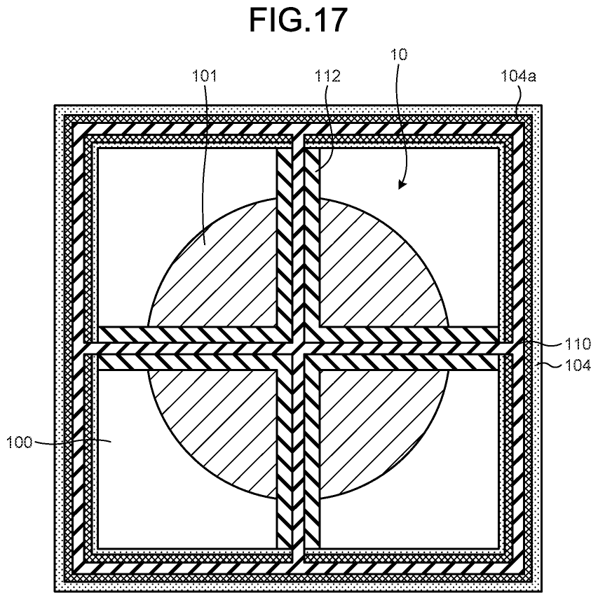

Next, modifications of the present embodiment will be described with reference to FIGS. 16 and 17. FIG. 16 is a schematic plan view illustrating an example of a detailed configuration of the pixel 10 according to Modification 1 of the present embodiment. FIG. 17 is a schematic plan view illustrating an example of a detailed configuration of the pixel 10 according to Modification 2 of the present embodiment.

In the present embodiment described above, as illustrated in FIG. 15, the n-type semiconductor region 101 has a substantially rectangular shape, but in the embodiments of the present disclosure, the shape of the n-type semiconductor region 101 is not limited to this shape. For example, in the present modification, as illustrated in FIG. 16, the n-type semiconductor region 101 may have a polygonal shape with a corner close to the high-concentration p-type semiconductor region 104a connected to the anode electrode 120 being chamfered. This causes the distance between the n-type semiconductor region 101 forming the avalanche multiplication region and the high-concentration p-type semiconductor region 104a to be long, and thus it is possible to alleviate the electric field concentration and to avoid the withstand voltage of the pixel 10 from decreasing.

For example, in the present modification, as illustrated in FIG. 17, the n-type semiconductor region 101 may have a substantially fan shape with a side close to the high-concentration p-type semiconductor region 104a connected to the anode electrode 120 having an arc shape (curved). This causes the distance between the n-type semiconductor region 101 forming the avalanche multiplication region and the high-concentration p-type semiconductor region 104a to be long, and thus it is possible to alleviate the electric field concentration and to avoid the withstand voltage of the pixel 10 from decreasing. Further, in the present modifications, there is no pointed shape in the n-type semiconductor region 101, which can alleviate the electric field concentration on corners.

### 6. Fifth Embodiment

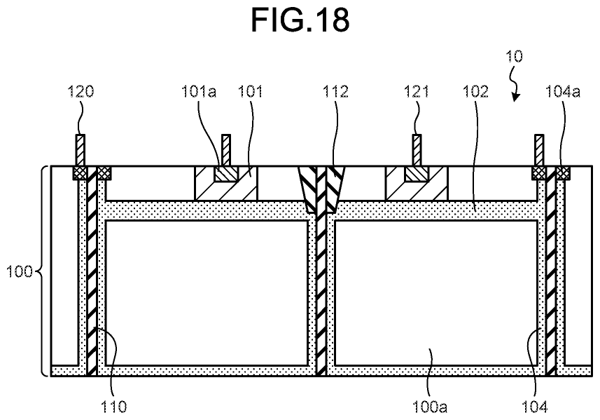

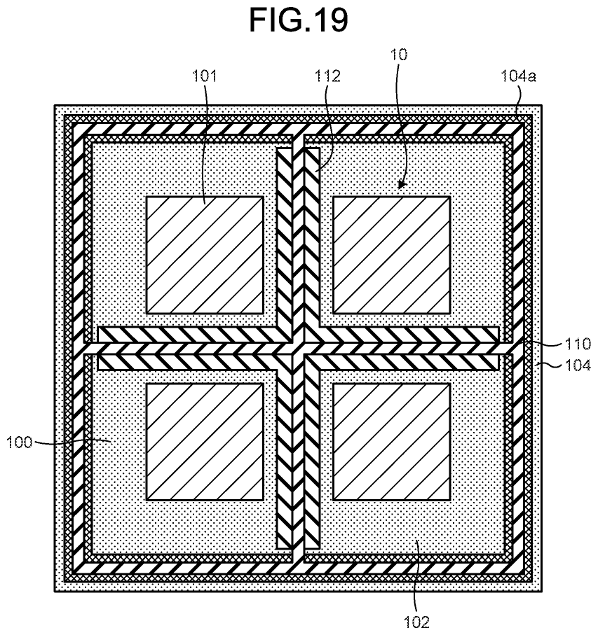

Next, a detailed configuration of the pixel 10 according to a fifth embodiment of the present disclosure will be described in detail with reference to FIGS. 18 and 19. FIG. 18 is a schematic sectional view illustrating an example of the detailed configuration of the pixel 10 according to the present embodiment. FIG. 19 is a schematic plan view illustrating the example of a detailed configuration of the pixel 10 according to the present embodiment.

As illustrated in FIGS. 18 and 19, in the present embodiment, the p-type semiconductor region (first semiconductor region) 102 forming the avalanche multiplication region may have a larger area than the n-type semiconductor region (second semiconductor region) 101 also forming the avalanche multiplication region. The present embodiment, having such a configuration, can form an avalanche multiplication region having a strong and uniform electric field. Further, in the present embodiment, the p-type semiconductor region 102 is present on the outer periphery of the avalanche multiplication region formed near the junction surface between the n-type semiconductor region 101 and the p-type semiconductor region 102 in plan view. This causes the electrons generated in the n-well region 100a by incident light to move to the avalanche multiplication region on the inner side but not to the outer periphery of the pixel 10. That is, the p-type semiconductor region 102 in the outer peripheral region has a shielding effect, and the electrons from the n-well region 100a move to the avalanche multiplication region in a barrierless manner. The barrierless structure from the n-well region 100a to the avalanche multiplication region can achieve low resistance and high PDE.

### 7. Sixth Embodiment

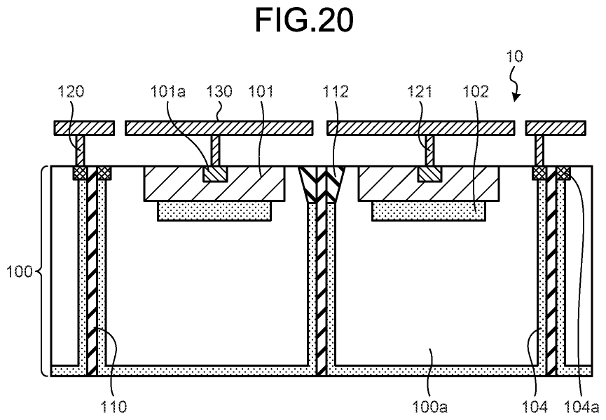

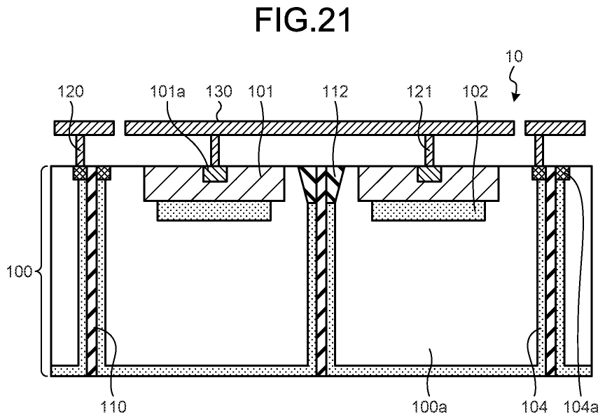

Next, a configuration of a section of the pixel 10 according to the fifth embodiment of the present disclosure and a modification thereof will be described in detail with reference to FIGS. 20 and 21. FIG. 20 is a schematic sectional view illustrating an example of a detailed configuration of the pixel 10 according to the present embodiment. FIG. 21 is a schematic sectional view illustrating the example of a detailed configuration of the pixel 10 according to a modification of the present embodiment.

In the present embodiment, as illustrated in FIG. 20, a wiring 130 may be formed above the anode electrode 120 and the cathode electrode 121 on the front surface side of the semiconductor substrate 100. For example, the wiring 130 is preferably formed using a metal material that reflects light, such as tungsten (W), aluminum (Al), or copper (Cu). Forming the wiring 130 with such a material enables the wiring 130 to reflect light transmitted through the semiconductor substrate 100, which can improve the sensitivity of the pixel 10.

In the modification of the present embodiment, as illustrated in FIG. 21, one wiring 130 provided above the front surface side of the semiconductor substrate 100 may be shared by pixels 10, that is, the pixels 10 may be electrically connected to each other via the wiring 130. In the present modification, since light transmitted through the semiconductor substrate 100 can be reflected by the wiring 130 in this manner, not only the sensitivity of the pixel 10 can improve, but also signal addition and calculation between adjacent pixels 10 can be performed, which can reduce the size of the pixel 10 and the size of the photodetector 501 on which the pixel 10 is mounted.

### 8. Seventh Embodiment

### 8.1 Detailed Configuration

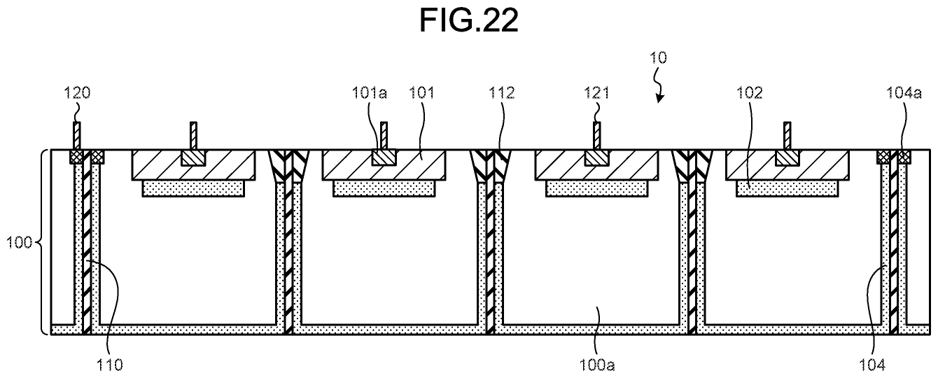

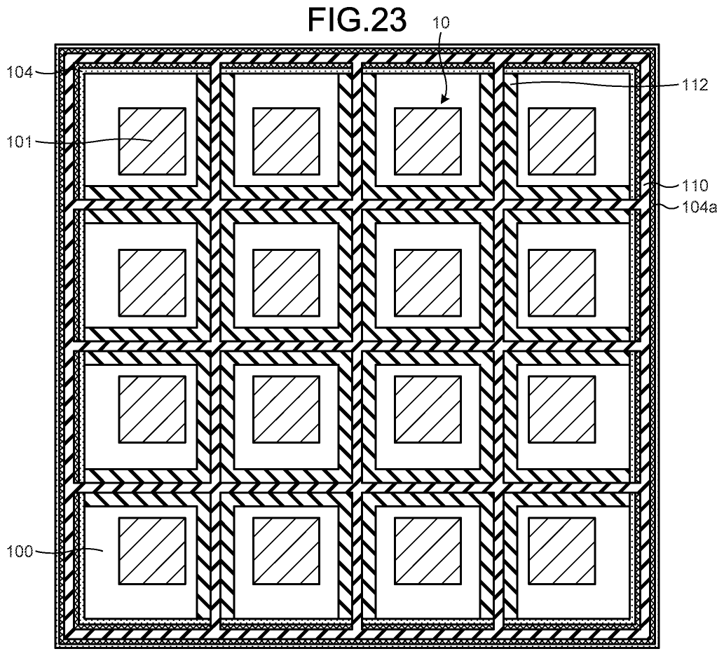

Next, a configuration of a section of the pixel 10 according to a seventh embodiment of the present disclosure and a modification thereof will be described in detail with reference to FIGS. 22 and 23. FIG. 22 is a schematic sectional view illustrating an example of a detailed configuration of the pixel 10 according to the present embodiment. FIG. 23 is a schematic plan view illustrating the example of a detailed configuration of the pixel 10 according to the present embodiment.

In the embodiments of the present disclosure, the pixel group is not limited to four pixels 10 arranged in 2×2. The pixel group may be, for example, composed of 16 pixels 10 arranged in 4×4. The number and arrangement of the pixels 10 constituting the pixel group are not limited. For example, in FIGS. 22 and 23, an example of the pixel group composed 16 pixels 10 arranged in 4×4 is illustrated as the seventh embodiment of the present disclosure.

In the present embodiment, as illustrated in FIG. 23, in the pixels 10 located at the four corners of the pixel group in the pixel group composed of 16 pixels 10 arranged in 4×4, the n-type semiconductor region 101 is provided such that the center point of the n-type semiconductor region 101 is closer to the center point of the pixel group than the center point of the corresponding pixel 10. With this configuration, in the present embodiment, the distance between the anode electrode 120 and the cathode electrode 121, in other words, the distance between the n-type semiconductor region 101 forming the avalanche multiplication region and the high-concentration p-type semiconductor region 104a is long. As a result, according to the present embodiment, since the electric field concentration can be alleviated, it is possible to avoid the withstand voltage of the pixel 10 from decreasing.

In the present embodiment, as illustrated in FIG. 23, the n-type semiconductor region 101 has a substantially rectangular shape. When the n-type semiconductor region 101 is formed in a substantially rectangular shape as illustrated, it is possible to secure a wide area of the avalanche multiplication region and can improve the PDE.

### 8.2 Modification

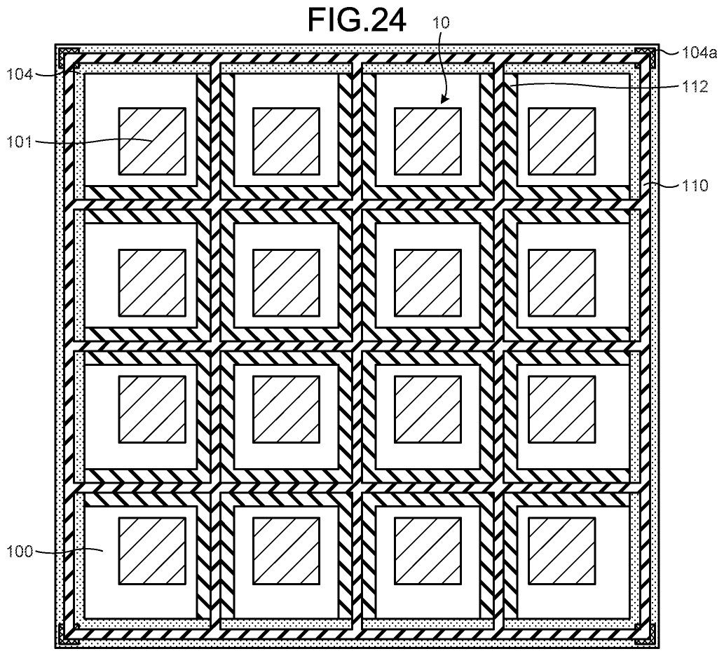

Next, a modification of the present embodiment will be described with reference to FIG. 24. FIG. 24 is a schematic plan view illustrating an example of a detailed configuration of the pixel 10 according to a modification of the present embodiment. In detail, in the present modification, as illustrated in FIG. 24, the high-concentration p-type semiconductor region 104a connected to the anode electrode 120 via the pixel isolation unit 110 is located only at the four corners of the pixel group similarly to the modification of the first embodiment, which causes the distance between the n-type semiconductor region 101 forming the avalanche multiplication region and the high-concentration p-type semiconductor region 104a to be long. As a result, according to the present modification, it is possible to alleviate the electric field concentration and further avoid the withstand voltage of the pixel 10 from decreasing.

### 9. Eighth Embodiment

### 9.1 Detailed Configuration

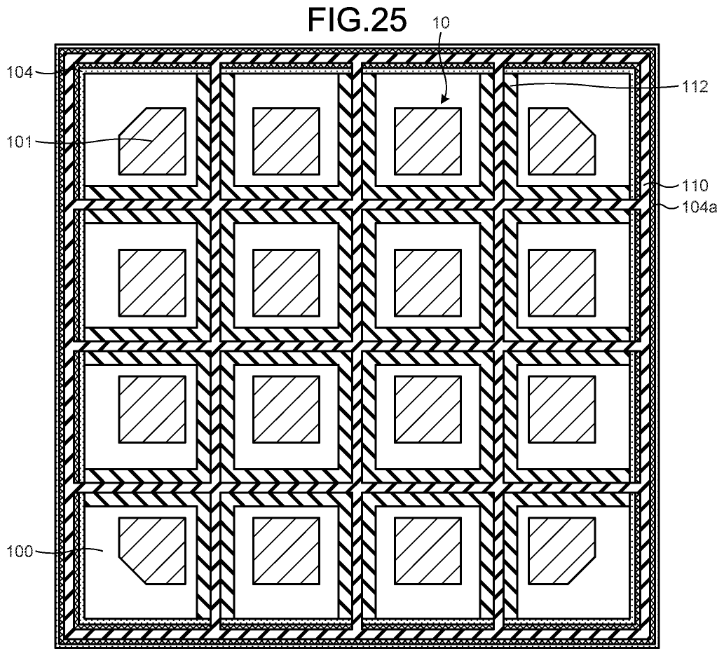

Next, a configuration of a section of the pixel 10 according to an eighth embodiment of the present disclosure will be described in detail with reference to FIG. 25. FIG. 25 is a schematic plan view illustrating an example of a detailed configuration of the pixel 10 according to the present embodiment.

In the above-described seventh embodiment of the present disclosure, as illustrated in FIG. 23, the n-type semiconductor region 101 has a substantially rectangular shape. The shape of the n-type semiconductor region 101 is not limited to this shape in the embodiments of the present disclosure. For example, in the present embodiment, as illustrated in FIG. 25, in the pixels 10 located at the four corners of the pixel group in the pixel group composed of 16 pixels 10 arranged in 4×4, the n-type semiconductor region 101 may have a polygonal shape with the corner close to the high-concentration p-type semiconductor region 104a connected to the anode electrode 120 being chamfered. This causes the distance between the n-type semiconductor region 101 forming the avalanche multiplication region and the high-concentration p-type semiconductor region 104a to be long, and thus it is possible to alleviate the electric field concentration and to avoid the withstand voltage of the pixel 10 from decreasing.

### 9.2 Modification

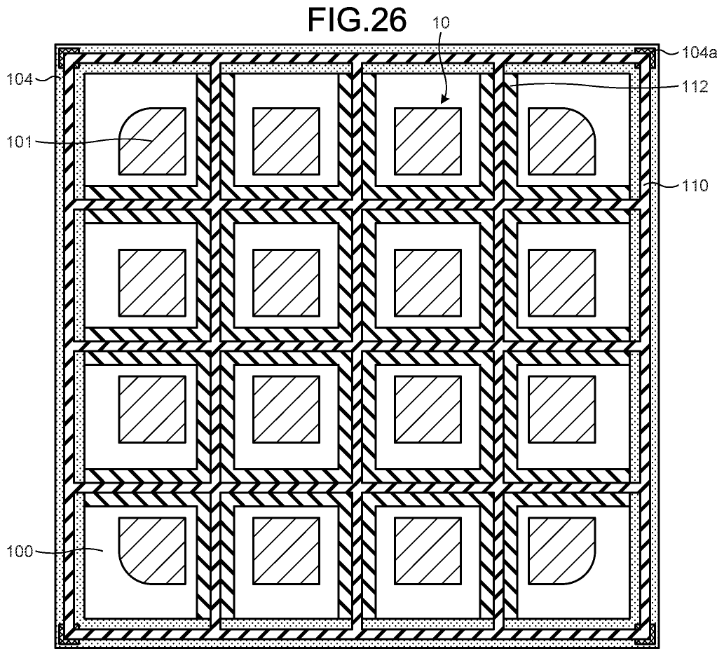

Next, a modification of the present embodiment will be described with reference to FIG. 26. FIG. 26 is a schematic plan view illustrating an example of a detailed configuration of the pixel 10 according to the modification of the present embodiment. For example, in the present modification, as illustrated in FIG. 26, in the pixels 10 located at the four corners in the pixel group composed of 16 pixels 10 arranged in 4×4, the n-type semiconductor region 101 may have a substantially rectangular shape with the corner close to the high-concentration p-type semiconductor region 104a connected to the anode electrode 120 having a rounded corner shape among the four corners of the n-type semiconductor region 101. This causes the distance between the n-type semiconductor region 101 forming the avalanche multiplication region and the high-concentration p-type semiconductor region 104a to be long, and thus it is possible to alleviate the electric field concentration and to avoid the withstand voltage of the pixel 10 from decreasing. In the present modification, there is no pointed shape in the n-type semiconductor region 101, which can alleviate the electric field concentration on corners.

### 10. Ninth Embodiment

### 10.1 Detailed Configuration

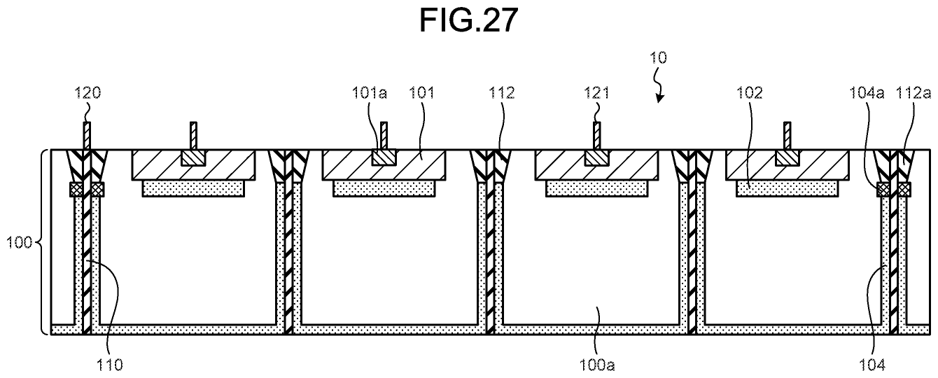

Next, a configuration of a section of the pixel 10 according to a ninth embodiment of the present disclosure will be described in detail with reference to FIGS. 27 and 28. FIG. 27 is a schematic sectional view illustrating an example of a detailed configuration of the pixel 10 according to the present embodiment. FIG. 28 is a schematic plan view illustrating the example of a detailed configuration of the pixel 10 according to the present embodiment. In the seventh embodiment described earlier, the isolation oxide film 112 is provided on the front surface side of the semiconductor substrate 100, on the hole accumulation region 104 where no anode electrode 120 is provided. However, in the present embodiment, as in the third embodiment, the isolation oxide film (second oxide film) 112a may be provided on the front surface side of the semiconductor substrate 100, on the hole accumulation region 104 where the anode electrode 120 is provided.

In detail, in the present embodiment, as illustrated in FIGS. 27 and 28, the separation oxide film (second oxide film) 112a of an STI structure having an oxide film (for example, a silicon oxide film) embedded in a groove provided near the surface of the semiconductor substrate 100 is provided on the front surface (surface opposite to the light receiving surface) side of the semiconductor substrate 100, on the hole accumulation region 104 where the anode electrode 120 is provided. The depth of the isolation oxide film 112 a is preferably and substantially equal to the depth of the n-type semiconductor region 101 forming the avalanche multiplication region from the viewpoint of improving the breakdown voltage, and is preferably above the position of the p-type semiconductor region 102 forming the avalanche multiplication region from the viewpoint of reducing occurrence of dark current, similarly to the isolation oxide film 112 described above. In the present embodiment, providing such an isolation oxide film 112a can reduce occurrence of crosstalk (color mixture) between pixels 10. Further, in the present embodiment, providing such an isolation oxide film 112a can avoid the impurity having p-type conductivity included in the hole accumulation region 104 from being present near the n-type semiconductor region 101, and thus, it is possible to alleviate the electric field concentration and to avoid the withstand voltage of the pixel 10 from decreasing.

### 10.2 Modification

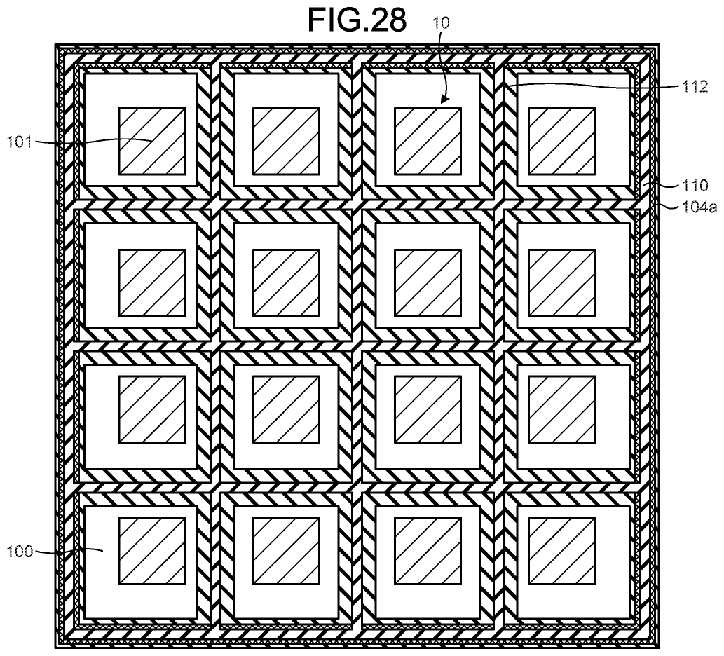

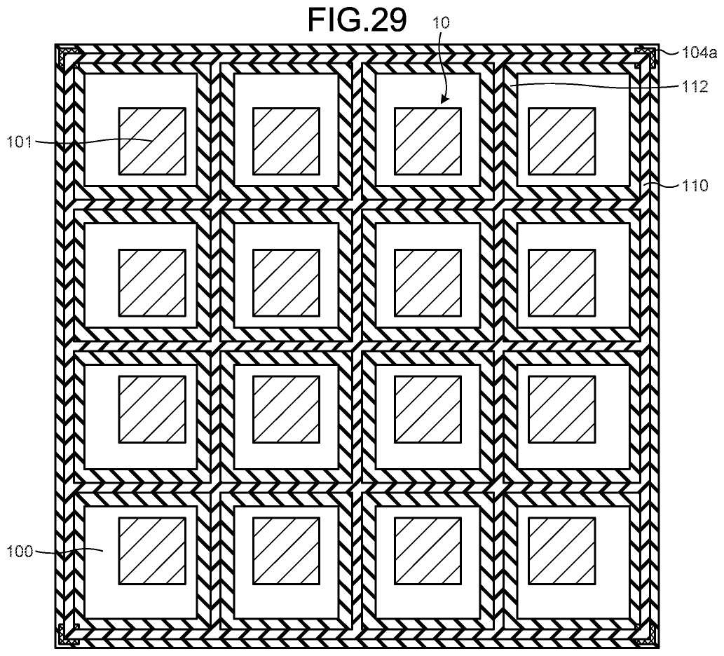

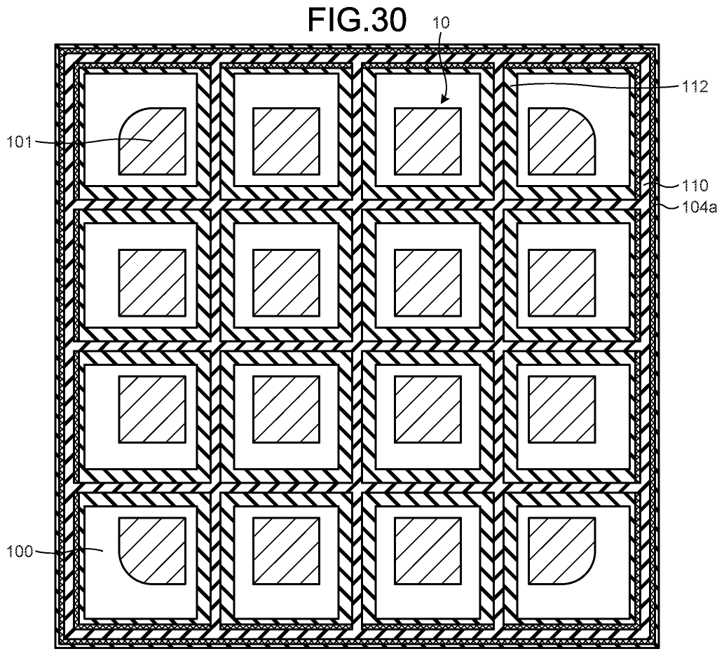

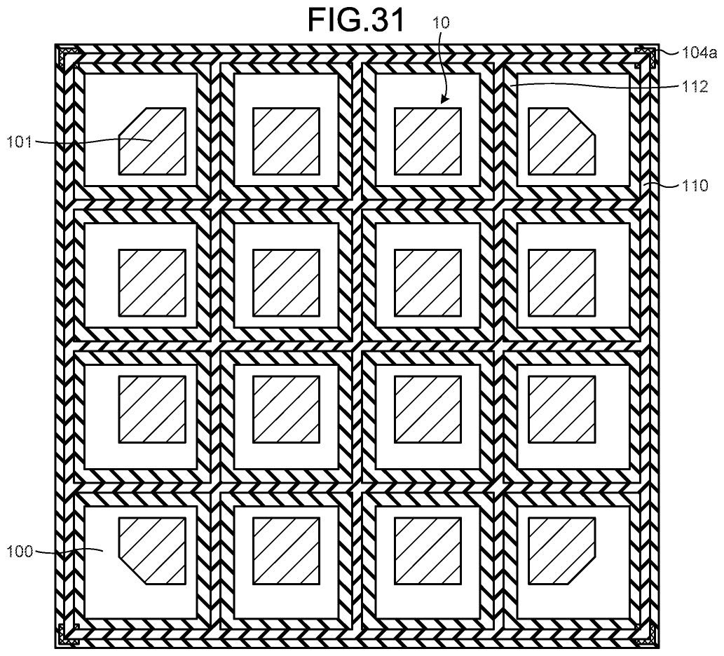

Next, modifications of the present embodiment will be described with reference to FIGS. 29 to 31. FIG. 29 is a schematic plan view illustrating an example of a detailed configuration of the pixel 10 according to Modification 1 of the present embodiment. FIG. 30 is a schematic plan view illustrating an example of a detailed configuration of the pixel 10 according to Modification 2 of the present embodiment. FIG. 31 is a schematic plan view illustrating an example of a detailed configuration of the pixel 10 according to Modification 3 of the present embodiment.

(Modification 1)

In Modification 1, as illustrated in FIG. 29, the high-concentration p-type semiconductor region 104a connected to the anode electrode 120 may be provided only at four corners of the pixel group composed of 16 pixels 10 arranged in 4×4, similarly to the modification of the first embodiment. With this configuration, in the present modification, the distance between the n-type semiconductor region 101 forming the avalanche multiplication region and the high-concentration p-type semiconductor region 104a becomes long, which can alleviate the electric field concentration and further avoid the withstand voltage of the pixel 10 from decreasing.

(Modification 2)

In Modification 2, as illustrated in FIG. 30, in the pixels 10 located at the four corners of the pixel group in the pixel group composed of 16 pixels 10 arranged in 4×4, the n-type semiconductor region 101 may have a substantially rectangular shape with the corner close to the high-concentration p-type semiconductor region 104a connected to the anode electrode 120 having a rounded corner shape among the four corners of the n-type semiconductor region 101. This causes the distance between the n-type semiconductor region 101 forming the avalanche multiplication region and the high-concentration p-type semiconductor region 104a to be long, and thus it is possible to alleviate the electric field concentration and to avoid the withstand voltage of the pixel 10 from decreasing. In the present modification, there is no pointed shape in the n-type semiconductor region 101, which can alleviate the electric field concentration on corners.

(Modification 3)

In Modification 3, as illustrated in FIG. 31, in the pixels 10 located at the four corners of the pixel group among the pixel group composed of 16 pixels 10 arranged in 4×4, the n-type semiconductor region 101 may have a polygonal shape with the corner close to the high-concentration p-type semiconductor region 104a connected to the anode electrode 120 being chamfered. This causes the distance between the n-type semiconductor region 101 forming the avalanche multiplication region and the high-concentration p-type semiconductor region 104a to be long, and thus it is possible to alleviate the electric field concentration and to avoid the withstand voltage of the pixel 10 from decreasing.

### 11. Tenth Embodiment

### 11.1 Detailed Configuration

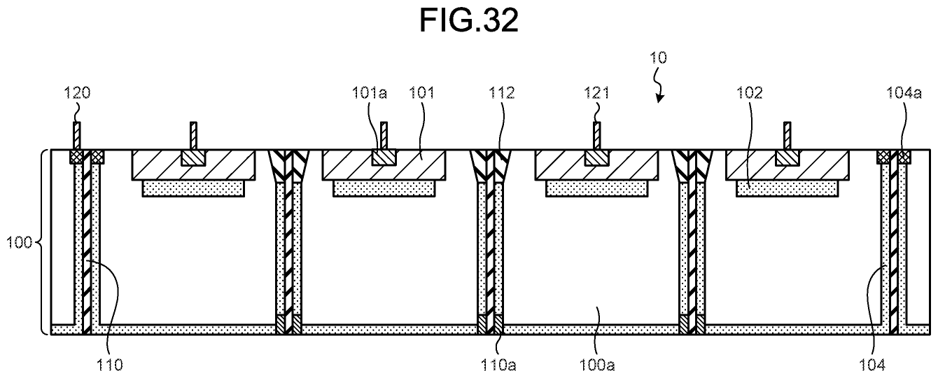

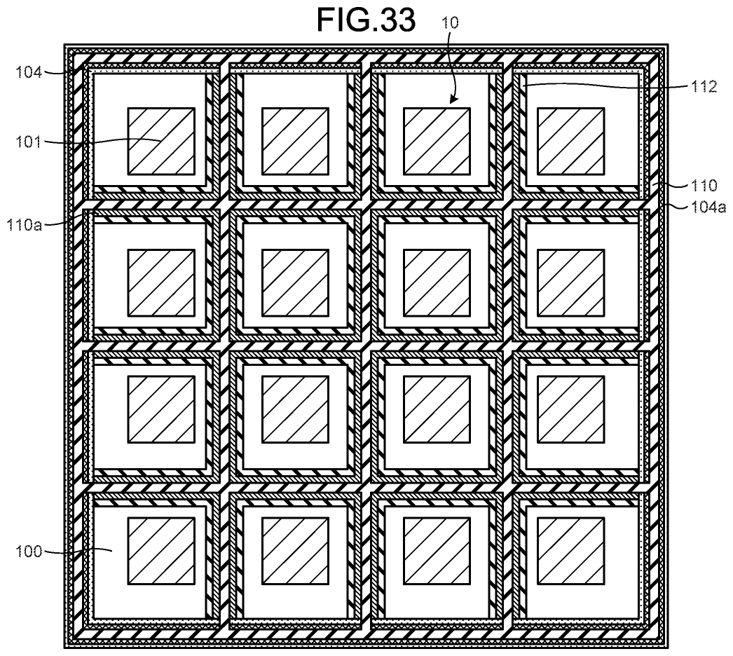

Next, a configuration of a section of the pixel 10 according to a tenth embodiment of the present disclosure will be described in detail with reference to FIGS. 32 and 33. FIG. 32 is a schematic sectional view illustrating an example of a detailed configuration of the pixel 10 according to the present embodiment. FIG. 33 is a schematic plan view illustrating the example of a detailed configuration of the pixel 10 according to the present embodiment. In the present embodiment, as illustrated in FIGS. 32 and 33, when ohmic contact of the hole accumulation region 104 is required on the back surface side of the semiconductor substrate 100, a contact unit 110a containing a p-type conductive impurity at a high concentration may be provided in a region near the back surface side of the semiconductor substrate 100 in the hole accumulation region 104. In detail, in the present embodiment, as illustrated in FIG. 32, the contact unit 110a is provided on the back surface (light receiving surface) of the hole accumulation region 104 where the isolation oxide film 112 is provided. The depth of the contact unit 110a is not limited to particular values, but it is preferable that the contact unit is provided deeper in the semiconductor substrate 100 from the viewpoint of withstand voltage.

### 11.2 Modification

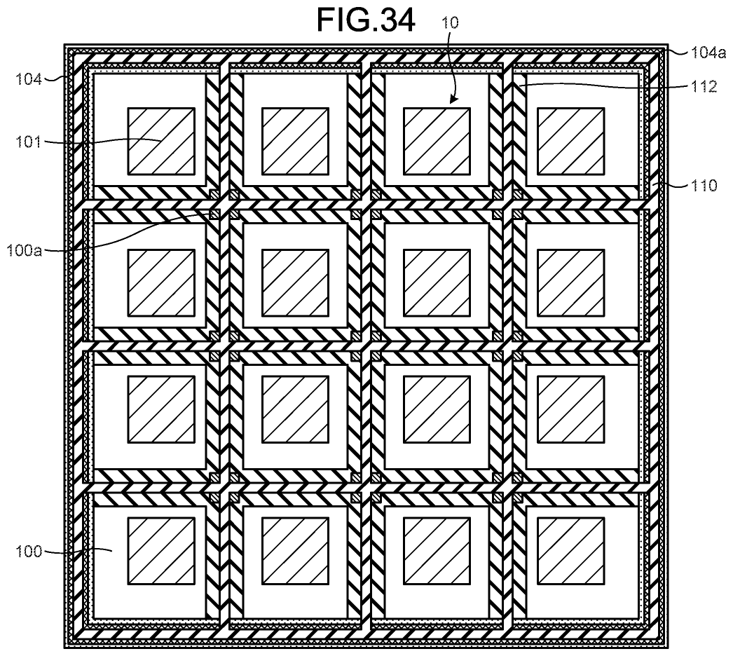

Next, a modification of the present embodiment will be described with reference to FIG. 34. FIG. 34 is a schematic plan view illustrating an example of a detailed configuration of the pixel 10 according to the modification of the present embodiment. In the present modification, as illustrated in FIG. 34, the contact unit 110a may be provided on a part of the back surface (light receiving surface) of the hole accumulation region 104 where the isolation oxide film 112 is provided, that is, along the intersection of the pixel isolation unit 110 surrounded by four pixels 10 in the pixel group.

### 12. Eleventh Embodiment

### 12.1 Production Method

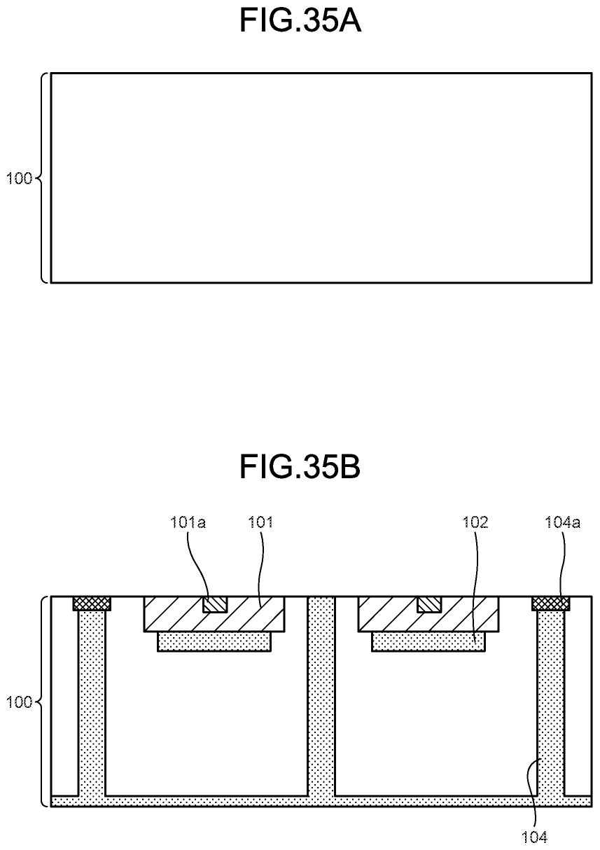

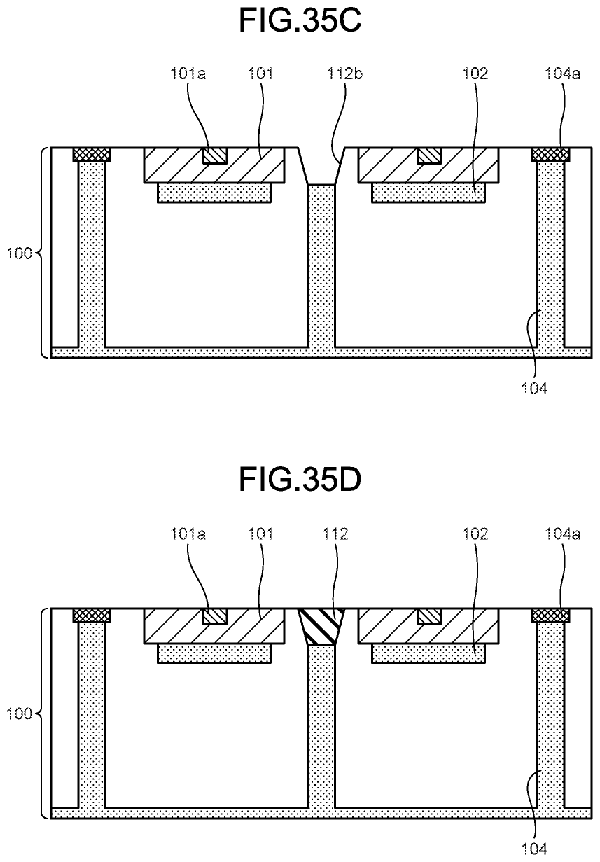

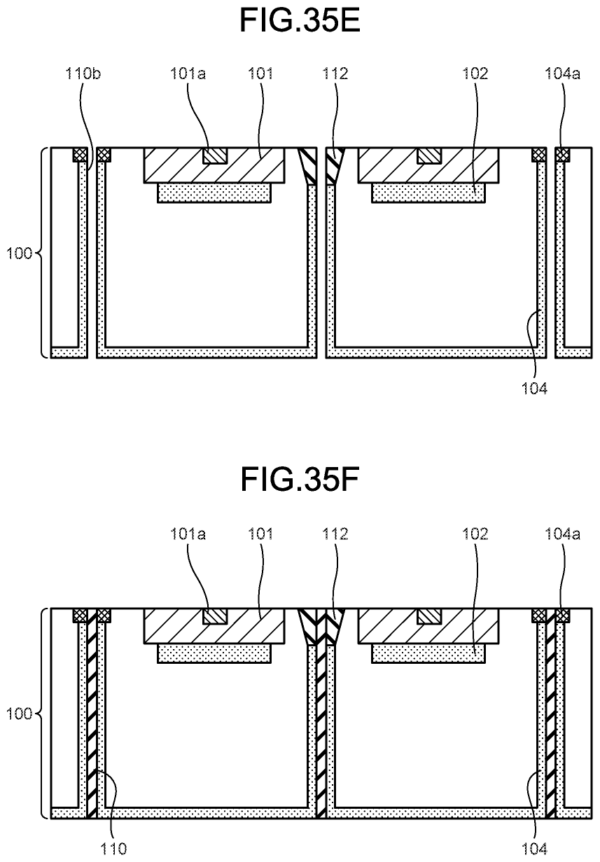

Next, a method for producing the pixel 10 according to the present embodiment will be described with reference to FIGS. 35A to 35F. FIGS. 35A to 35F are schematic views for explaining the method for producing the pixel 10 according to the present embodiment, and in detail, each drawing is a sectional view corresponding to the schematic view of a configuration of a section of the pixel 10 in FIG. 7 at each stage in the production process.

For example, as illustrated in FIG. 35A, prepare the semiconductor substrate 100 made of a silicon substrate. Next, as illustrated in FIG. 35B, perform ion implantation of impurities on regions corresponding to the n-type semiconductor region 101, the high-concentration n-type semiconductor region 101a, the p-type semiconductor region 102, the hole accumulation region 104, and the high-concentration p-type semiconductor region 104a. In the present embodiment, the order of the ion implantation is not limited, but ion implantation for the high-concentration n-type semiconductor region 101a and the high-concentration p-type semiconductor region 104a are preferably performed as late as possible to reduce thermal diffusion. Forming the hole accumulation region 104 is not limited by ion implantation, and it can be formed by solid-phase diffusion, induction by a fixed charge film, or the like.

Further, as illustrated in FIG. 35C, form a groove 112b for the isolation oxide film 112 on the front surface of the semiconductor substrate 100 between adjacent pixels 10. Then, as illustrated in FIG. 35D, embed an oxide film such as a silicon oxide film in the groove 112b to form the isolation oxide film 112.

Next, as illustrated in FIG. 35E, to form the pixel isolation unit 110, form a groove 110b penetrating the semiconductor substrate 100. Then, as illustrated in FIG. 35F, embed an oxide film such as a silicon oxide film in the groove 110b to form the pixel isolation unit 110. The pixel 10 according to the embodiments of the present disclosure may be thus obtained.

In the present embodiment, the order of the steps is not limited to the above-described order, and the high-concentration n-type semiconductor region 101a and the high-concentration p-type semiconductor region 104a may be performed in the following order to reduce thermal diffusion. For example, implant impurities into regions corresponding to the n-type semiconductor region 101, the p-type semiconductor region 102, and the hole accumulation region 104 other than the high-concentration n-type semiconductor region 101a and the high-concentration p-type semiconductor region 104a, and thereafter form the isolation oxide film 112 and the pixel isolation unit 110. Next, perform ion implantation of impurities on regions corresponding to the high-concentration n-type semiconductor region 101a and the high-concentration p-type semiconductor region 104a.

In the case of a back-illuminated pixel 10, a process of bonding another semiconductor substrate (not illustrated) to the semiconductor substrate 100 is further performed between the processes illustrated in FIGS. 35E and 35F.

### 12.2 Modification

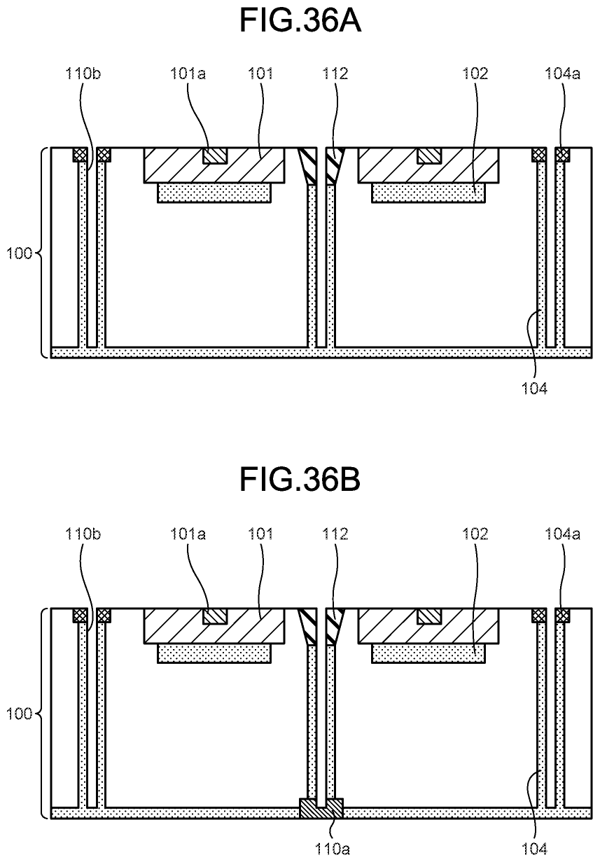

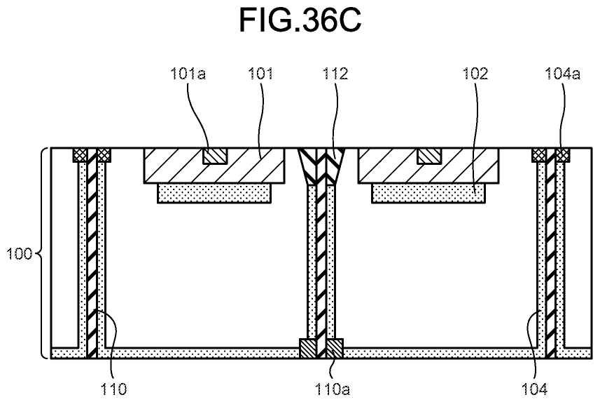

Next, a method for producing the pixel 10 according to a modification of the present embodiment will be described with reference to FIGS. 36A to 35C. FIGS. 36A to 36C are schematic views for explaining the method for producing the pixel 10 according to the modification of the present embodiment, and in detail, each drawing is a sectional view corresponding to the schematic view of a configuration of a section of the pixel 10 in FIG. 7 at each stage in the production process.

First, in the present modification, perform sequentially the steps illustrated in FIGS. 35A to 35D described earlier.

Then, in the present modification, as illustrated in FIG. 36A, to form the pixel isolation unit 110, form the groove 110b that penetrates the semiconductor substrate 100 from the back surface to the middle of the substrate and does not penetrate the front surface of the semiconductor substrate 100. That is, in the present modification, a part of the semiconductor substrate 100 near the front surface side is left.

Further, as illustrated in FIG. 36B, thermally diffuse the impurity having p-type conductivity from the part of the semiconductor substrate 100 near the front surface side left in the previous step to form the contact unit 110a. In the present modification, the contact unit 110a may be formed by ion-implanting a p-type conductive impurity into a part of the vicinity of the front surface side of the semiconductor substrate 100 left in the previous step.

Then, as illustrated in FIG. 36C, embed an oxide film such as a silicon oxide film in the groove 110b to form the pixel isolation unit 110. The pixel 10 according to the present modification may be thus obtained.

### 13. Conclusion

In this manner, according to the embodiments and modifications of the present disclosure, the distance between the anode electrode 120 and the cathode electrode 121, in other words, the distance between the n-type semiconductor region 101 forming the avalanche multiplication region and the high-concentration p-type semiconductor region 104a is made long. As a result, according to the present embodiment, since the electric field concentration can be alleviated, it is possible to avoid the withstand voltage of the pixel 10 from decreasing. Further, according to the present embodiment, the sensitivity of the pixel 10 can further improve since it is possible to increase the size of the avalanche multiplication region formed in the junction region between the p-type semiconductor region 102 and the n-type semiconductor region 101 with a pixel reduced in size.

In the embodiments of the present disclosure described above, the semiconductor substrate 100 is not necessarily a silicon substrate, and may be another substrate (for example, a silicon on insulator (SOI) substrate, a SiGe substrate, or the like). In the semiconductor substrate 100, a semiconductor structure or the like may be formed in such various substrates.

In the embodiments of the present disclosure described above, the conductivity types of the semiconductor substrate 100, each semiconductor region, and the like described above may be reversed, and for example, the present embodiment can be applied to the pixel 10 using holes as signal charges. That is, in the embodiments of the present disclosure described above, the pixel 10 including the photodiode 20 in which the first conductivity type is p-type, the second conductivity type is n-type, and electrons are used as signal charges has been described, but the embodiments of the present disclosure are not limited to such an example. For example, the embodiments of the present disclosure may be applied to the pixel 10 having the photodiode 20 in which the first conductivity type is n-type, the second conductivity type is p-type, and holes are used as signal charges.

Further, the pixel 10 according to the embodiments of the present disclosure is not limited to being applied to the photodetector 501 applied to the distance measurement system 611. For example, the pixel 10 according to the embodiments of the present disclosure may be applied to an imaging device that captures a distribution of the incident light amount of visible light as a detected image. The present embodiments may also be applied to an imaging device that captures a distribution of incident amounts of infrared rays, X-rays, particles, or the like as an image, or an imaging device (physical amount distribution detection device) such as a fingerprint detection sensor that detects a distribution of other physical amounts such as pressure and capacitance and captures the distribution as an image, for example.

In the embodiments of the present disclosure, examples of a method of forming each layer, each film, each element, and the like described above include a physical vapor deposition (PVD) method, a chemical vapor deposition (CVD) method, and the like. Examples of the PVD method include a vacuum vapor deposition method using resistance heating or high frequency heating, an electron beam (EB) vapor deposition method, various sputtering methods (magnetron sputtering method, radio frequency (RF)-direct current (DC) coupled bias sputtering method, electron cyclotron resonance (ECR) sputtering method, counter target sputtering method, high frequency sputtering method, and the like), an ion plating method, a laser ablation method, a molecular beam epitaxy (MBE) method, and a laser transfer method. Examples of the CVD method include a plasma CVD method, a thermal CVD method, a metal organic (MO)-CVD method, and a photo CVD method. Further, other methods include electrolytic plating methods, electroless plating methods, spin coating methods; immersion methods; cast methods; micro-contact printing; drop cast methods; various printing methods such as a screen printing method, an inkjet printing method, an offset printing method, a gravure printing method, or a flexographic printing method; stamping methods; spray methods; various coating methods such as an air doctor coater method, a blade coater method, a rod coater method, a knife coater method, a squeeze coater method, a reverse roll coater method, a transfer roll coater method, a gravure coater method, a kiss coater method, a cast coater method, a spray coater method, a slit orifice coater method, and a calender coater method. Examples of a patterning method of each layer include chemical etching such as shadow mask, laser transfer, or photolithography, and physical etching using ultraviolet rays, laser, or the like. In addition, examples of flattening technique include a chemical mechanical polishing (CMP) method, a laser flattening method, and a reflow method. That is, the pixel 10 according to the embodiments of the present disclosure can be easily and inexpensively produced using an existing semiconductor device production process.

Each step in the production method according to the embodiments of the present disclosure described above does not have to be processed in the described order. For example, each step may be processed in an appropriately changed order. Further, the method used in each step does not have to be performed according to the described method, and may be performed by other methods.

### 14. Application Example

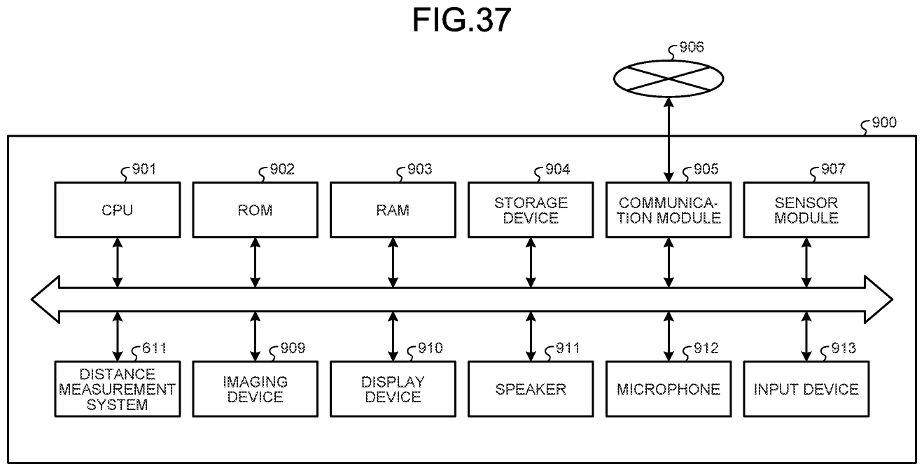

The above-described distance measurement system 611 may be applied to various electronic devices such as cameras having a distance measurement function, smartphones having a distance measurement function, and industrial cameras provided in a production line, for example. A configuration example of a smartphone 900 as an electronic device to which the technology of the present disclosure is applied will be described with reference to FIG. 37. FIG. 37 is a block diagram illustrating a configuration example of the smartphone 900 as an electronic device to which the distance measurement system 611 according to an embodiment of the present disclosure is applied.

As illustrated in FIG. 37, the smartphone 900 includes a central processing unit (CPU) 901, a read only memory (ROM) 902, and a random access memory (RAM) 903. The smartphone 900 also includes a storage device 904, a communication module 905, and a sensor module 907. The smartphone 900 further includes the above-described distance measurement system 611 as well as an imaging device 909, a display device 910, a speaker 911, a microphone 912, an input device 913, and a bus 914. The smartphone 900 may include a processing circuit such as a digital signal processor (DSP) instead of or in addition to the CPU 901.

The CPU 901 functions as an arithmetic processing device and a control device, and it controls the overall operation in the smartphone 900 or a part thereof according to various programs recorded in the ROM 902, the RAM 903, the storage device 904, or the like. The ROM 902 stores programs, operation parameters, and the like used by the CPU 901. The RAM 903 primarily stores programs used in the execution of the CPU 901, parameters that appropriately change in the execution, and the like. The CPU 901, the ROM 902, and the RAM 903 are connected to each other by the bus 914. The storage device 904 is a device for data storage configured as an example of a storage unit of the smartphone 900. The storage device 904 is composed of a magnetic storage device such as a hard disk drive (HDD), a semiconductor storage device, an optical storage device, or the like, for example. The storage device 904 stores programs and various data executed by the CPU 901, various data acquired from the outside, and the like.

The communication module 905 is a communication interface including, for example, a communication device for connecting to the communication network 906. The communication module 905 may be a communication card for wired or wireless local area network (LAN), Bluetooth (registered trademark), wireless USB (WUSB), or the like, for example. The communication module 905 may also be a router for optical communication, a router for asymmetric digital subscriber line (ADSL), a modem for various types of communication, or the like. The communication module 905 transmits and receives signals and the like to and from the Internet or other communication devices using a predetermined protocol such as TCP/IP. The communication network 906 connected to the communication module 905 is a network connected in a wired or wireless manner, and is, for example, the Internet, a home LAN, infrared communication, satellite communication, or the like.

The sensor module 907 includes, for example, various sensors such as a motion sensor (for example, an acceleration sensor, a gyro sensor, or a geomagnetic sensor), a biological information sensor (for example, a pulse sensor, a blood pressure sensor, or a fingerprint sensor), or a position sensor (for example, a global navigation satellite system (GNSS) receiver).

The distance measurement system 611 is provided on the surface of the smartphone 900, and can acquire, for example, distances and three-dimensional shapes of the subjects 612, 613 facing the surface as distance measurement results.

The imaging device 909 is provided on the surface of the smartphone 900, and can image an object 800 or the like located around the smartphone 900. In detail, the imaging device 909 may include an imaging element (not illustrated) such as a complementary MOS (CMOS) image sensor, and a signal processing circuit (not illustrated) that performs imaging signal processing on a signal photoelectrically converted by the imaging element. The imaging device 909 may further include an optical system mechanism (not illustrated) composed of an imaging lens, a diaphragm mechanism, a zoom lens, a focus lens, and the like, and a drive system mechanism (not illustrated) that controls the operation of the optical system mechanism. Then, the imaging element collects incident light from the object 800 as an optical image, and the signal processing circuit photoelectrically converts the formed optical image in units of pixels, reads a signal of each pixel as an imaging signal, and performs image processing to acquire a captured image.

The display device 910 is provided on the surface of the smartphone 900, and it may be a display device such as a liquid crystal display (LCD) or an organic electro luminescence (EL) display, for example. The display device 910 can display an operation screen, a captured image acquired by the above-described imaging device 909, and the like.

The speaker 911 can output, for example, a call voice, a voice accompanying video contents displayed by the display device 910 described above, and the like to the user.

The microphone 912 can collect, for example, a call voice of the user, a voice including a command to activate a function of the smartphone 900, and a voice in a surrounding environment of the smartphone 900.

The input device 913 is a device operated by the user with a button, a keyboard, a touch panel, a mouse, or the like. The input device 913 includes an input control circuit that generates an input signal based on information input by the user and outputs the input signal to the CPU 901. The user can input various data and give an instruction on a processing operation to the smartphone 900 by operating the input device 913.

The above is a configuration example of the smartphone 900. Each of the above-described components may be configured by using a versatile member, or may be configured by hardware specialized for the function of each component. Such a configuration may be appropriately changed according to the technical level at the time of implementation.

### 15. Supplement

Although the preferred embodiments of the present disclosure have been described in detail with reference to the accompanying drawings, the technical scope of the present disclosure is not limited to such examples. It is obvious that a person having ordinary knowledge in the technical field of the present disclosure can conceive various changes or modifications within the scope of the technical idea described in the claims, and it is naturally understood that these also belong to the technical scope of the present disclosure.

The effects described in the present specification are merely illustrative or exemplary, and are not restrictive. That is, the technology according to the present disclosure can exhibit other effects obvious to those skilled in the art from the description of the present specification together with or instead of the above effects.

The present technology may also take the following configurations.

(1) A light receiving element provided in a semiconductor substrate and surrounded by a pixel isolation wall, the light receiving element comprising:
a photoelectric conversion unit that is provided in the semiconductor substrate and generates a charge with light incident from a light receiving surface of the semiconductor substrate;
a multiplication region that is provided on an opposite side of the photoelectric conversion unit from the light receiving surface and amplifies a charge from the photoelectric conversion unit;
a cathode unit provided on a surface of the multiplication region, the surface being on the opposite side from the light receiving surface;
a hole accumulation region provided to cover the light receiving surface and an inner side surface of the pixel isolation wall; and
an anode unit provided on a part of a surface of the hole accumulation region covering the inner side surface of the pixel isolation wall, the part of the surface being on the opposite side from the light receiving surface,
wherein when the semiconductor substrate is viewed from above a surface on the opposite side from the light receiving surface,
the multiplication region is provided such that a center point of the multiplication region is farther from the anode unit than a center point of the light receiving element.
   (2) The light receiving element according to (1), further comprising an oxide film located on a portion where the anode unit is not provided in the surface of the hole accumulation region opposite to the light receiving surface.
   (3) A photodetector comprising:
a pixel group including a plurality of pixels arranged in a matrix in a semiconductor substrate; and
a pixel isolation wall surrounding each of the pixels and isolating the pixels from each other,
wherein each of the pixels includes:
a photoelectric conversion unit that is provided in the semiconductor substrate and generates a charge with light incident from a light receiving surface of the semiconductor substrate;
a multiplication region that is provided on an opposite side of the photoelectric conversion unit from the light receiving surface and amplifies a charge from the photoelectric conversion unit;
a cathode unit provided on a surface of the multiplication region, the surface being on the opposite side from the light receiving surface;
a hole accumulation region provided to cover the light receiving surface and an inner side surface of the pixel isolation wall; and
an anode unit provided on a part of a surface of the hole accumulation region covering the inner side surface of the pixel isolation wall surrounding the pixel group, the part of the surface being on the opposite side from the light receiving surface, and
when the semiconductor substrate is viewed from above a surface on the opposite side from the light receiving surface,
in at least one of the plurality of pixels included in the pixel group,
the multiplication region is provided such that a center point of the multiplication region is closer to a center point of the pixel group than a center point of a corresponding pixel in the at least one of the plurality of pixels.
   (4) The photodetector according to (3), further comprising a first oxide film located on a portion where the anode unit is not provided in the surface of the hole accumulation region on the opposite side from the light receiving surface.
   (5) The photodetector according to (3), wherein the anode unit is provided on a surface of the hole accumulation region covering one of four corners of the pixel isolation wall surrounding the pixel group, the surface being on the opposite side from the light receiving surface.
   (6) The photodetector according to (4), further comprising a second oxide film provided on a surface of the anode unit, the surface being on an opposite side from the hole accumulation region.
   (7) The photodetector according to (6),
wherein the multiplication region includes:
a first semiconductor region provided on the photoelectric conversion unit and having a first conductivity type; and
a second semiconductor region provided on the first semiconductor region and having a second conductivity type that is a conductivity type opposite to the first conductivity type.
   (8) The photodetector according to (7), wherein the respective second semiconductor regions of the pixels in the pixel group are isolated from each other by the first oxide film.
   (9) The photodetector according to (7),
wherein when the semiconductor substrate is viewed from above the surface on the opposite side from the light receiving surface,
the second semiconductor region is wider than the first semiconductor region.
   (10) The photodetector according to (7),
wherein when the semiconductor substrate is viewed from above the surface on the opposite side from the light receiving surface,
the first semiconductor region is wider than the second semiconductor region.
   (11) The photodetector according to any one of (3) to (10), the pixels further include, respectively, wirings made of a light reflecting material and provided above the cathode unit.
   (12) The photodetector according to (11), wherein the wirings of the pixels are electrically connected to each other.
   (13) The photodetector according to any one of (7) to (10),
wherein when the semiconductor substrate is viewed from above the surface on the opposite side from the light receiving surface,
the second semiconductor region has a substantially rectangular shape.
   (14) The photodetector according to (13),
wherein when the semiconductor substrate is viewed from above the surface on the opposite side from the light receiving surface,
in at least one of the plurality of pixels included in the pixel group,
one of four corners of the second semiconductor region has a rounded shape.
   (15) The photodetector according to (13),
wherein when the semiconductor substrate is viewed from above the surface on the opposite side from the light receiving surface,
in at least one of the plurality of pixels included in the pixel group,
one of four corners of the second semiconductor region is chamfered.
   (16) The photodetector according to any one of (7) to (10),
wherein when the semiconductor substrate is viewed from above the surface on the opposite side from the light receiving surface,
the second semiconductor region has a substantially fan shape.
   (17) The photodetector according to (4), further comprising a contact unit located on at least a part of the light receiving surface of the hole accumulation region where the first oxide film is provided.
   (18) A distance measurement system comprising:
an illumination device that emits irradiation light; and
a photodetector that receives reflected light obtained by reflecting the irradiation light on a subject,
wherein the photodetector includes:
a pixel group including a plurality of pixels arranged in a matrix in a semiconductor substrate; and
a pixel isolation wall surrounding each of the pixels and isolating the pixels from each other,
wherein each of the pixels includes:
a photoelectric conversion unit that is provided in the semiconductor substrate and generates a charge with light incident from a light receiving surface of the semiconductor substrate;
a multiplication region that is provided on an opposite side of the photoelectric conversion unit from the light receiving surface and amplifies a charge from the photoelectric conversion unit;
a cathode unit provided on a surface of the multiplication region, the surface being on the opposite side from the light receiving surface;
a hole accumulation region provided to cover the light receiving surface and an inner side surface of the pixel isolation wall; and
an anode unit provided on a part of a surface of the hole accumulation region covering the inner side surface of the pixel isolation wall surrounding the pixel group, the part of the surface being on the opposite side from the light receiving surface, and
when the semiconductor substrate is viewed from above a surface on the opposite side from the light receiving surface,
in at least one of the plurality of pixels included in the pixel group,
the multiplication region is provided such that a center point of the multiplication region is closer to a center point of the pixel group than a center point of a corresponding pixel in the at least one of the plurality of pixels.

### REFERENCE SIGNS LIST

10 Pixel
20 Photodiode
22 Constant Current Source
24 Inverter
26 Transistor
100 Semiconductor Substrate
100a n-Well Region
101 n-Type Semiconductor Region
101a High-Concentration n-Type Semiconductor Region
102 p-Type Semiconductor Region
104 Hole Accumulation Region
104a High-Concentration p-Type Semiconductor Region
110 Pixel Isolation Unit
110a Contact Unit
110b, 112b Groove
112, 112a Isolation Oxide Film
120 Anode Electrode
121 Cathode Electrode
130 Wiring
501 Photodetector
511 Pixel Drive Unit
512 Pixel Array Unit
513 Mux
514 Time Measurement Unit
515 Input/Output Unit
522 Pixel Drive Line
611 Distance Measurement System
612, 613 Subject
621 Illumination Device
622 Imaging Device
631 Illumination Control Unit
632 Light Source
641 Imaging Unit
642 Control Unit
643 Display Unit
644 Storage Unit
651 Lens
653 Signal Processing Circuit

What is claimed is:

1. A light receiving element provided in a semiconductor substrate and surrounded by a pixel isolation wall, the light receiving element comprising:
a photoelectric conversion unit that is provided in the semiconductor substrate and generates a charge with light incident from a light receiving surface of the semiconductor substrate;
a multiplication region that is provided on an opposite side of the photoelectric conversion unit from the light receiving surface and amplifies a charge from the photoelectric conversion unit;
a cathode unit provided on a surface of the multiplication region, the surface being on the opposite side from the light receiving surface;
a hole accumulation region provided to cover the light receiving surface and an inner side surface of the pixel isolation wall; and
an anode unit provided on a part of a surface of the hole accumulation region covering the inner side surface of the pixel isolation wall, the part of the surface being on the opposite side from the light receiving surface,
wherein when the semiconductor substrate is viewed from above a surface on the opposite side from the light receiving surface, and
wherein the multiplication region is provided such that a center point of the multiplication region is farther from the anode unit than a center point of the light receiving element.

2. The light receiving element according to claim 1, further comprising an oxide film located on a portion where the anode unit is not provided in the surface of the hole accumulation region opposite to the light receiving surface.

3. A photodetector, comprising:
a pixel group including a plurality of pixels arranged in a matrix in a semiconductor substrate; and
a pixel isolation wall surrounding each of the pixels and isolating the pixels from each other,
wherein each of the pixels includes:
a photoelectric conversion unit that is provided in the semiconductor substrate and generates a charge with light incident from a light receiving surface of the semiconductor substrate;
a multiplication region that is provided on an opposite side of the photoelectric conversion unit from the light receiving surface and amplifies a charge from the photoelectric conversion unit;
a cathode unit provided on a surface of the multiplication region, the surface being on the opposite side from the light receiving surface;
a hole accumulation region provided to cover the light receiving surface and an inner side surface of the pixel isolation wall; and
an anode unit provided on a part of a surface of the hole accumulation region covering the inner side surface of the pixel isolation wall surrounding the pixel group, the part of the surface being on the opposite side from the light receiving surface, and
when the semiconductor substrate is viewed from above a surface on the opposite side from the light receiving surface,
in at least one of the plurality of pixels included in the pixel group,
the multiplication region is provided such that a center point of the multiplication region is closer to a center point of the pixel group than a center point of a corresponding pixel in the at least one of the plurality of pixels.

4. The photodetector according to claim 3, further comprising a first oxide film located on a portion where the anode unit is not provided in the surface of the hole accumulation region on the opposite side from the light receiving surface.

5. The photodetector according to claim 3, wherein the anode unit is provided on a surface of the hole accumulation region covering one of four corners of the pixel isolation wall surrounding the pixel group, the surface being on the opposite side from the light receiving surface.

6. The photodetector according to claim 4, further comprising a second oxide film provided on a surface of the anode unit, the surface being on an opposite side from the hole accumulation region.

7. The photodetector according to claim 6,
wherein the multiplication region includes:
a first semiconductor region provided on the photoelectric conversion unit and having a first conductivity type; and
a second semiconductor region provided on the first semiconductor region and having a second conductivity type that is a conductivity type opposite to the first conductivity type.

8. The photodetector according to claim 7, wherein the respective second semiconductor regions of the pixels in the pixel group are isolated from each other by the first oxide film.

9. The photodetector according to claim 7,
wherein when the semiconductor substrate is viewed from above the surface on the opposite side from the light receiving surface,
the second semiconductor region is wider than the first semiconductor region.

10. The photodetector according to claim 7,
wherein when the semiconductor substrate is viewed from above the surface on the opposite side from the light receiving surface,
the first semiconductor region is wider than the second semiconductor region.

11. The photodetector according to claim 3, the pixels further include, respectively, wirings made of a light reflecting material and provided above the cathode unit.

12. The photodetector according to claim 11, wherein the wirings of the pixels are electrically connected to each other.

13. The photodetector according to claim 7,
wherein when the semiconductor substrate is viewed from above the surface on the opposite side from the light receiving surface,
the second semiconductor region has a substantially rectangular shape.

14. The photodetector according to claim 13,
wherein when the semiconductor substrate is viewed from above the surface on the opposite side from the light receiving surface,
in at least one of the plurality of pixels included in the pixel group,
one of four corners of the second semiconductor region has a rounded shape.

15. The photodetector according to claim 13,
wherein when the semiconductor substrate is viewed from above the surface on the opposite side from the light receiving surface,
in at least one of the plurality of pixels included in the pixel group,
one of four corners of the second semiconductor region is chamfered.

16. The photodetector according to claim 7,
wherein when the semiconductor substrate is viewed from above the surface on the opposite side from the light receiving surface,
the second semiconductor region has a substantially fan shape.

17. The photodetector according to claim 4, further comprising a contact unit located on at least a part of the light receiving surface of the hole accumulation region where the first oxide film is provided.

18. A distance measurement system, comprising:
an illumination device that emits irradiation light; and
a photodetector that receives reflected light obtained by reflecting the irradiation light on a subject,
wherein the photodetector includes:
a pixel group including a plurality of pixels arranged in a matrix in a semiconductor substrate; and
a pixel isolation wall surrounding each of the pixels and isolating the pixels from each other,
wherein each of the pixels includes:
a photoelectric conversion unit that is provided in the semiconductor substrate and generates a charge with light incident from a light receiving surface of the semiconductor substrate;
a multiplication region that is provided on an opposite side of the photoelectric conversion unit from the light receiving surface and amplifies a charge from the photoelectric conversion unit;
a cathode unit provided on a surface of the multiplication region, the surface being on the opposite side from the light receiving surface;
a hole accumulation region provided to cover the light receiving surface and an inner side surface of the pixel isolation wall; and
an anode unit provided on a part of a surface of the hole accumulation region covering the inner side surface of the pixel isolation wall surrounding the pixel group, the part of the surface being on the opposite side from the light receiving surface, and
when the semiconductor substrate is viewed from above a surface on the opposite side from the light receiving surface,
in at least one of the plurality of pixels included in the pixel group,
the multiplication region is provided such that a center point of the multiplication region is closer to a center point of the pixel group than a center point of a corresponding pixel in the at least one of the plurality of pixels.
